(19) United States
(12) Patent Application Publication
(10) Pub. No.: US 2025/0311418 A1
(43) Pub. Date: Oct. 2, 2025

(54) INTEGRATED CIRCUIT DEVICE WITH HETEROGENEOUS SEMICONDUCTOR ORIENTATION

(71) Applicant: Intel Corporation, Santa Clara, CA (US)

(72) Inventors: Abhishek A. Sharma, Portland, OR (US); Sagar Suthram, Portland, OR (US); Tahir Ghani, Portland, OR (US); Wilfred Gomes, Portland, OR (US); Anand S. Murthy, Portland, OR (US)

(73) Assignee: Intel Corporation, Santa Clara, CA (US)

(21) Appl. No.: 18/618,175

(22) Filed: Mar. 27, 2024

(51) Int. Cl. H01L 27/092; H01L 21/8238; H01L 29/06; H01L 29/10; H01L 29/423; H01L 29/775; H01L 29/78; H01L 29/786

(52) U.S. Cl. CPC H10D 84/856; H10D 30/43; H10D 30/6211; H10D 30/6735; H10D 30/6757; H10D 62/121; H10D 62/292; H10D 84/0167; H10D 84/038

(57) ABSTRACT

IC devices including semiconductor structures with heterogenous orientation are disclosed. An example IC device includes a P-type transistor and an N-type transistor. The N-type transistor may include an N-type semiconductor structure having a surface with Miller indices (111). The P-type transistor may include a P-type semiconductor structure having a surface with Miller indices (100). The two semiconductor structures may be separated by an electrical insulator. The N-type semiconductor structure may be formed over a first device region. The P-type semiconductor structure may be formed on a second device region. The IC device may be formed through layer transfer, which results in the two semiconductor structures being stacked over each other. The two semiconductor structures may include Ge. The P-type semiconductor structure may be between the N-type semiconductor structure and an additional semiconductor structure in the IC device that includes Si. A semiconductor structure may be fin-shaped or nanoribbon-shaped.

### TECHNICAL FIELD

This disclosure relates generally to the field of semiconductor devices, and more specifically, to integrated circuit (IC) devices.

### BACKGROUND

IC fabrication may include a process of patterning semiconductor devices components (e.g., transistor, capacitors, resistors, etc.) on a wafer. The process for patterning transistors on a wafter may include a complementary metal-oxide-semiconductor (CMOS) process, in which metal-oxide-semiconductor field-effect transistors (MOSFETs) can be fabricated. There are two types of MOSFETS: P-type and N-type. P-type MOSFET (also referred to as “PMOS” or “PMOS transistor”) has P-type semiconductor, while N-type MOSFET (also referred to as “NMOS”) has N-type semiconductor. Semiconductors in CMOS transistors usually have crystal structures. The three-value Miller index notation is typically used as directional parameters of crystal structures.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 is a perspective view of an example IC device including semiconductor structures with heterogeneous orientation, according to some embodiments of the disclosure.

FIGS. 2A-2C illustrate lattice planes in an example crystal structure, according to some embodiments of the disclosure.

FIGS. 3A-3C illustrate an example process of forming semiconductor structures with [111] crystal direction, according to some embodiments of the disclosure.

FIGS. 4A-4C illustrate an example process of forming semiconductor structures [100] crystal direction, according to some embodiments of the disclosure.

FIGS. 5A-5F illustrate an example process of stacking semiconductor structures with heterogeneous orientation, according to some embodiments of the disclosure.

FIGS. 6A-6C illustrate an example pair of unaligned wafers, according to some embodiments of the disclosure.

FIG. 7A is a perspective view of an example IC device including nanoribbon-shaped semiconductor structures with heterogeneous orientation, according to some embodiments of the disclosure.

FIG. 7B is a perspective view of an example IC device including fin-shaped semiconductor structures with heterogeneous orientation, according to some embodiments of the disclosure.

FIG. 8 is a perspective view of an example IC device including semiconductor structures with heterogeneous orientation and heterogeneous shape, according to some embodiments of the disclosure.

FIG. 9A is an electric circuit diagram of an example memory cell, according to some embodiments of the present disclosure.

FIG. 9B provides a top-down plan view of one example implementation of the memory cell, according to some embodiments of the present disclosure.

FIG. 10 is an electric circuit diagram of a memory array, according to some embodiments of the present disclosure.

FIGS. 11A-11B are top views of a wafer and dies that may include one or more CMOS circuits with heterogeneous semiconductor orientations, according to some embodiments of the disclosure.

FIG. 12 is a side, cross-sectional view of an example IC package that may include one or more IC devices having heterogeneous semiconductor orientations, according to some embodiments of the disclosure.

FIG. 13 is a cross-sectional side view of an IC device assembly that may include components having one or more IC devices implementing heterogeneous semiconductor orientations, according to some embodiments of the disclosure.

FIG. 14 is a block diagram of an example computing device that may include one or more components with heterogeneous semiconductor orientations, according to some embodiments of the disclosure.

FIG. 15 is a block diagram of an example processing device that may include one or more CMOS circuits with heterogeneous semiconductor orientations, according to some embodiments of the disclosure.

### DETAILED DESCRIPTION

The systems, methods, and devices of this disclosure each have several innovative aspects, no single one of which is solely responsible for all of the desirable attributes disclosed herein. Details of one or more implementations of the subject matter described in this specification are set forth in the description below and the accompanying drawings.

Embodiments of the present disclosure are applicable to different types of memory devices. Some embodiments of the present disclosure may refer to static random-access memory (SRAM). Other embodiments of the present disclosure may refer to dynamic random-access memory (DRAM). However, embodiments of the present disclosure may be equally applicable to memory cells implemented other technologies. Thus, in general, memory cells/arrays described herein may be implemented as standalone SRAM devices, DRAM devices, or any other volatile or nonvolatile memory cells/arrays. A memory device usually includes a plurality of memory cells. A memory cell includes a memory element, which stores information, and an access transistor, which is coupled to the memory element and controls access to the memory element. Memory cells have, conventionally, been implemented with access transistors being front end of line (FEOL), logic-process based, transistors implemented in an upper-most layer of a semiconductor substrate.

Many IC devices have PMOS transistors paired with PMOS transistors. For instance, an IC device, such as a memory device, may include a CMOS circuit that includes a NMOS transistor and an PMOS transistor. NMOS has electrons as majority charge carriers and holes as minority charge carriers. PMOS has hole as majority charge carriers and electrons as minority charge carriers. Electrons usually have higher mobility than holes. For instance, the mobility of electrons can be approximately two or three times the mobility of holes. Currently available CMOS circuits usually include PMOS with semiconductor having the [110] crystal direction and NMOS with semiconductor having the [100] crystal direction. Currently available technologies for fabricating such CMOS circuits typically make PMOS transistors larger and NMOS transistors smaller to render NMOS resistance the same or similar as PMOS resistance, which can result in the rise time and fall time of NMOS gates being equal or almost equal to the rise time and fall time of PMOS gates. For instance, many CMOS technologies make the size of PMOS transistors approximately twice the size of NMOS transistors. However, such a significant size difference can cause fabrication challenges or asymmetric performance in CMOS circuits. Therefore, improved technologies for fabricating CMOS circuits are needed.

Embodiments of the present disclosure may improve on at least some of the challenges and issues described above by providing IC devices including semiconductor structures with heterogenous orientations. For example, a CMOS circuit including a pair of PMOS transistor and NMOS transistor may have heterogenous orientation, in which a semiconductor structure in the PMOS transistor may have a crystal direction [100] while a semiconductor structure of the PMOS transistor may have a crystal direction [111]. Such heterogenous orientation can gain symmetric performance by balancing the mobility of charge carriers in the two types of transistors and optimize the mobility of charge carriers. Therefore, the performance balance between the two types of transistors can be improved. Also, the fabrication process for making the sizes of the two types of transistors different can be avoided.

An example IC device in the present disclosure may include a first semiconductor structure, a second semiconductor structure, and a third semiconductor structure, which may be stacked over each other. The first semiconductor structure may include a channel of an N-type transistor and may have a surface, the Miller indices of which is (111), corresponding to the [111] crystal direction. The surface may have a larger area than one or more other surfaces of the first semiconductor structure. In some embodiments, the surface may be the largest surface of the first semiconductor structure. The second semiconductor structure may include a channel of a P-type transistor and may have a surface, the Miller indices of which is (100), corresponding to the [100] crystal direction. The surface may have a larger area than one or more other surfaces of the second semiconductor structure. In some embodiments, the surface may be the largest surface of the second semiconductor structure.

An angle between the two crystal directions may be over 50 degrees, e.g., approximately 54.7 degrees. In some embodiments, the two surfaces may be in parallel. In other embodiments, the two surfaces may be perpendicular to each other. The second semiconductor structure may be between the first semiconductor structure and the third semiconductor structure. In some embodiments, the first semiconductor structure and the second semiconductor structure may include the same semiconductor material, such as germanium (Ge), indium gallium arsenide (InGaAs), gallium arsenide (GaAs), indium arsenide (InAs), silicon germanium (SiGe), gallium nitride (GaN), other proper materials, or some combination thereof. The third semiconductor structure may include a different semiconductor material, such as silicon (Si). In other embodiments, the first semiconductor structure and the second semiconductor structure may have different semiconductor materials. The first semiconductor structure or the second semiconductor structure may have a non-planar structure, e.g., a fin, nanoribbon, nanowire, and so on. In some embodiments, the first semiconductor structure has the same shape as the second semiconductor structure. In other embodiments, the first semiconductor structure has a different shape from the second semiconductor structure.

The IC device may be fabricated using layer transfer. In an example, the first semiconductor structure and the second semiconductor structure are formed over different device regions (e.g., substrates). The first semiconductor structure and a fourth semiconductor structure may be formed over a first substrate to produce a first semiconductor assembly. The second semiconductor structure and the third semiconductor structure may be formed over a second substrate to produce a second semiconductor assembly. In some embodiments, the crystal directions of the first semiconductor structure and the fourth semiconductor structure are aligned. The crystal directions of the second semiconductor structure and the third semiconductor structure are aligned. The first semiconductor assembly or the second semiconductor assembly may also include one or more insulator layers or one or more dielectric layers. The first semiconductor assembly may be flipped upside down and bonded with the second semiconductor assembly, e.g., through an insulator layer. The insulator layer may be between the first semiconductor structure and the second semiconductor structure. After the bonding, the fourth semiconductor structure may be removed. One or more insulator layers or one or more dielectric layers in the first semiconductor assembly may also be removed.

It should be noted that, in some settings, the term “nanoribbon” has been used to describe an elongated semiconductor structure that has a substantially rectangular transverse cross-section (e.g., a cross-section in a plane perpendicular to the longitudinal axis of the structure), while the term “nanowire” has been used to describe a similar structure but with a substantially circular or square transverse cross-sections. In the following, a single term “nanoribbon” is used to describe an elongated semiconductor structure independent of the shape of the transverse cross-section. Thus, as used herein, the term “nanoribbon” is used to cover elongated semiconductor structures that have substantially rectangular transverse cross-sections (possibly with rounded corners), elongated semiconductor structures that have substantially square transverse cross-sections (possibly with rounded corners), elongated semiconductor structures that have substantially circular or elliptical/oval transverse cross-sections, as well as elongated semiconductor structures that have any polygonal transverse cross-sections. A longitudinal axis of a structure refers to a line (e.g., an imaginary line) that runs down the center of the structure in a direction perpendicular to a transverse cross-section of the structure.

In the following, some descriptions may refer to a particular S source or drain (S/D) region or contact being either a source region/contact or a drain region/contact. However, unless specified otherwise, which region/contact of a transistor is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

The systems, methods and devices of this disclosure each have several innovative aspects, no single one of which is solely responsible for the all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. As used herein, a “logic state” (or, alternatively, a “state” or a “bit” value) of a memory cell may refer to one of a finite number of states that the cell can have, e.g., logic states “1” and “0,” each state represented by a different voltage of the capacitor of the cell, while “READ” and “WRITE” memory access or operations refer to, respectively, determining/sensing a logic state of a memory cell and programming/setting a logic state of a memory cell. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20% of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−5-20% of a target value based on the context of a particular value as described herein or as known in the art. Also, the term “or” refers to an inclusive “or” and not to an exclusive “or.”

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the term “or” refers to an inclusive “or” and not to an exclusive “or.” The phrase “A and/or B” or the phase “A or B” means (A), (B), or (A and B). For the purposes of the present disclosure, the phrase “A, B, and/or C” or the phase “A, B, or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

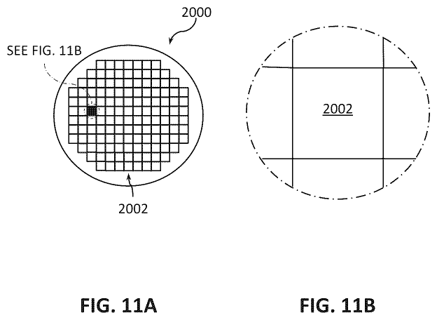

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense. For convenience, if a collection of drawings designated with different letters are present, e.g., FIGS. 11A-11B, such a collection may be referred to herein without the letters, e.g., as “FIG. 11.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Various IC devices with stacked memory devices as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

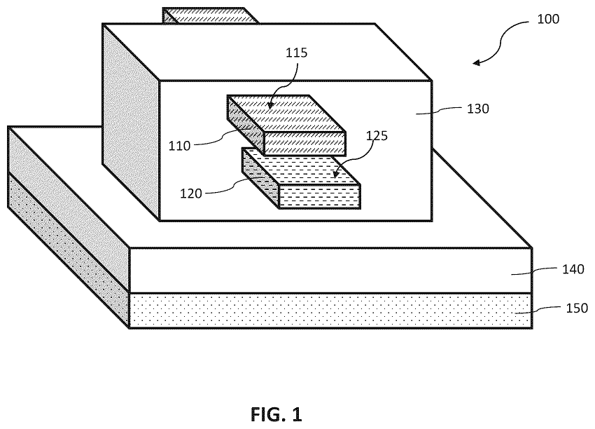

FIG. 1 is a perspective view of an example IC device 100 including semiconductor structures 110 and 120 with heterogeneous orientation, according to some embodiments of the disclosure. The IC device 100 also includes a conductive structure 130, an insulator layer 140, and a device region 150. In other embodiments, the IC device 100 may include fewer, more, or different components. For example, the IC device 100 may include a different number of semiconductor structures, conductive structures, insulator layers, support structures, and so on. As another example, the IC device 100 may include semiconductor structures of different shapes.

The semiconductor structure 110 includes the source region, channel region, and drain region of a first transistor in the IC device 100. The portion of the semiconductor structure 110 that is wrapped around by the conductive structure 130 may be the channel region of the first transistor. The other portions of the semiconductor structure 110 may be the source region and drain region, respectively. The first transistor also includes a gate, which may include at least part of the conductive structure 130. In some embodiments, at least part of the conductive structure 130 constitutes a gate electrode of the first transistor. The first transistor may include a gate insulator (not shown in FIG. 1) that is between the gate electrode and the channel region.

The semiconductor structure 120 includes the source region, channel region, and drain region of a second transistor in the IC device 100. The portion of the semiconductor structure 120 that is wrapped around by the conductive structure 130 may be the channel region of the second transistor. The other portions of the semiconductor structure 120 may be the source region and drain region, respectively. The second transistor also includes a gate, which may include at least part of the conductive structure 130. In some embodiments, at least part of the conductive structure 130 constitutes a gate electrode of the second transistor. The second transistor may include a gate insulator (not shown in FIG. 1) that is between the gate electrode and the channel region.

The first transistor and the second transistor constitute at least part of a CMOS circuit in the IC device 100. In some embodiments, the first transistor may be an N-type transistor. For instance, the first transistor is an NMOS transistor. The second transistor may be a P-type transistor. For instance, the second transistor is an NMOS transistor. The first transistor may have electrons as charge carriers, while the second transistor may have holes as charge carriers. To gain a symmetric performance of the CMOS circuit, the semiconductor structure 110 and the semiconductor structure 120 may have different crystal directions. For instance, at least a portion of the semiconductor structure 110 may be in the (111) lattice plane of the crystal structure of the semiconductor material in the semiconductor structure 110. The crystal direction of the semiconductor structure 110 is [111]. At least a portion of the semiconductor structure 120 may be in the (100) lattice plane of the crystal structure of the semiconductor material in the semiconductor structure 120. The crystal direction of the semiconductor structure 120 is [100]. In some embodiments, the semiconductor material in the semiconductor structure 110 and the semiconductor material in the semiconductor structure 120 may be the same semiconductor material. Examples of the semiconductor material include Ge, InGaAs, GaAs, InAs, SiGe, GaN, other proper materials, or some combination thereof.

In the embodiments of FIG. 1, a surface 115 of the semiconductor structure 110 may be in the (111) plane, and a surface 125 of the semiconductor structure 120 may be in the (111) plane. The surface 115 is in parallel with the surface 125. Even though the surface 115 and the surface 125 are each the top surface of the corresponding semiconductor structure in FIG. 1, the surface 115 or 125 may be a side surface or the bottom surface of the corresponding semiconductor structure in some embodiments. Also, the surface 115 may be perpendicular to the surface 125 in some embodiments. For example, the surface 115 may be the top or bottom surface, while the surface 125 may be a side surface. As another example, the surface 125 may be the top or bottom surface, while the surface 115 may be a side surface.

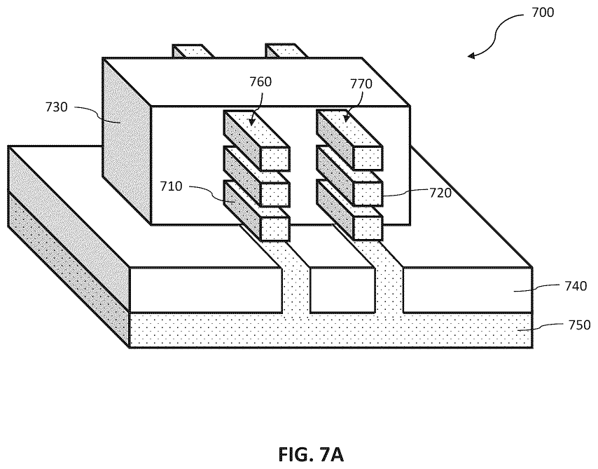

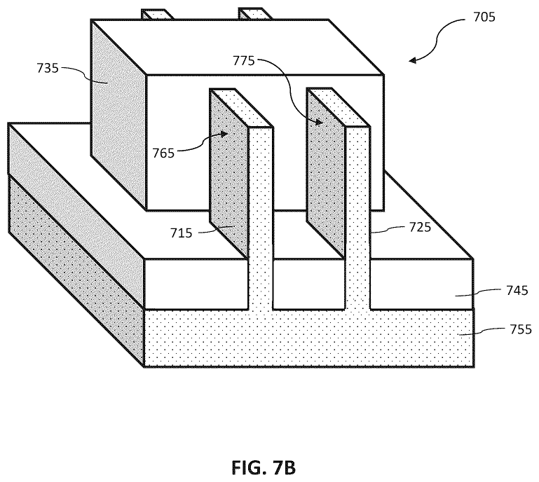

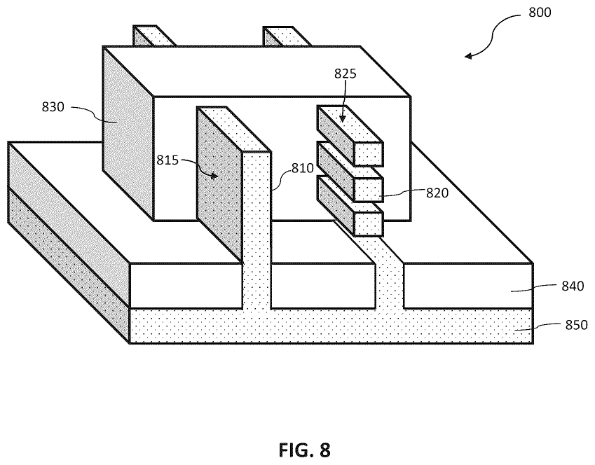

The first transistor or the second transistor may be a field-effect transistor (FET), such as metal-oxide-semiconductor FET (MOSFET), tunnel FET (TFET), gate-all-around (GAA) transistor, other types of FET, or a combination of both. The semiconductor structure 110 and semiconductor structure 120 may each be a non-planar structure. A non-planar structure is a three-dimensional structure, such as fin, nanowire, or nanoribbon. A non-planar structure may have a longitudinal axis and a transvers cross-section perpendicular to the longitudinal axis. In some embodiments, a dimension of the non-planar structure along the longitudinal axis may be greater than dimensions along other directions, e.g., directions along axes perpendicular to the longitudinal axis. In the embodiments of FIG. 1, the semiconductor structure 110 and semiconductor structure 120 are both nanoribbons. In other embodiments, the semiconductor structure 110 or semiconductor structure 120 may have a different shape, such as fin, nanowire, and so on. Certain aspects of semiconductor structures having different shapes are described below in conjunction with FIGS. 7A, 7B, and 8.

As described above, the semiconductor structure 110 and semiconductor structure 120 provides the channel regions, source regions, and drain regions of the two transistors, respectively. In each transistor, the source region and the drain region may be connected to the channel region. A source region or drain region may include a semiconductor material with dopants. An N-type source region or drain region may include a semiconductor material with N-type dopants. N-type dopants can introduce additional electrons into the crystal lattice of a semiconductor material and are also known as “donor” impurities. A P-type source region or drain region may include a semiconductor material with P-type dopants. P-type dopants can introduce additional holes into the crystal lattice and are also known as “acceptor” impurities. Example N-type dopants include Te, S, As, tin (Sn), Si, Ga, Se, S, In, Al, Cd, chlorine (CI), iodine (I), fluorine (F), and so on. Example P-type dopants include beryllium (Be), Zn, magnesium (Mg), Sn, P, Te, lithium (Li), sodium (Na), Ga, Cd, and so on.

In an N-type transistor, the source and drain regions may be doped with N-type dopants with dopant concentrations of at least 10¹⁷ dopants per cubic centimeter (cm⁻³), or more, e.g., with dopant concentrations of at least 10¹⁸ cm⁻³ or with dopant concentrations of at least 10²⁰ cm⁻³ to create regions with an excess of electrons that can serve as the majority charge carriers during operation of the N-type transistor. In a P-type transistor, the source and drain regions may be doped with P-type dopants with dopant concentrations of at least 10¹⁷ cm⁻³, or more, e.g., with dopant concentrations of at least 10¹⁸ cm⁻³ or with dopant concentrations of at least 10²⁰ cm⁻³ to create regions with an excess of holes (or deficiencies of electrons) that can serve as the majority charge carriers during operation of the P-type transistor. In some embodiments, a source region or drain region may be highly doped, e.g., with dopant concentrations of about 1·10²¹ cm⁻³, in order to advantageously form Ohmic contacts with the respective S/D contacts (also sometimes interchangeably referred to as “S/D electrodes”), although these regions may also have lower dopant concentrations and may form Schottky contacts in some implementations. Irrespective of the exact doping levels, the source region and the drain region of a transistor may be the regions having dopant concentration higher than in other regions, e.g., higher than a dopant concentration in the channel region, and, therefore, may be referred to as “highly doped” (HD) regions.

A semiconductor material of the source region or the drain region may be a Group IV material, a compound of Group IV materials, a Group Ill/V material, a compound of Group Ill/V materials, a Group II/VI material, a compound of Group II/VI materials, or other semiconductor materials. Example Group II materials include zinc (Zn), cadmium (Cd), and so on. Example Group Ill materials include aluminum (AI), boron (B), indium (In), gallium (Ga), and so on. Example Group IV materials include Si, Ge, carbon (C), etc. Example Group V materials include nitrogen (N), phosphorus (P), arsenic (As), antimony (Sb), and so on. Example Group VI materials include sulfur (S), selenium (Se), tellurium (Te), oxygen (O), and so on. A compound of Group IV materials can be a binary compound, such as SiC, SiGe, and so on. A compound of Group Ill/V materials can be a binary, tertiary, or quaternary compound, such as GaN, InN, and so on. A compound of Group II/VI materials can be a binary, tertiary, or quaternary compounds, such as CdSe, CdS, CdTe, ZnO, ZnSe, ZnS, ZnTe, CdZnTe, CZT, HgCdTe, HgZnTe, and so on.

In some embodiments, the dopants in the source region and the drain region are the same type. In other embodiments, the dopants of the source region and the drain region may be different (e.g., opposite) types. In an example, the source region has N-type dopants, and the drain region has P-type dopants. In another example, the source region has P-type dopants, and the drain region has N-type dopants. Example N-type dopants include Te, S, As, tin (Sn), Si, Ga, Se, S, In, Al, Cd, chlorine (CI), iodine (I), fluorine (F), and so on. Example P-type dopants include beryllium (Be), Zn, magnesium (Mg), Sn, P, Te, lithium (Li), sodium (Na), Ga, Cd, and so on.

In some embodiments, the dopants in the source region and the drain region of a transistor are the same type. In other embodiments, the dopants of the source region and the drain region may be different (e.g., opposite) types. In an example, the source region has N-type dopants, and the drain region has P-type dopants. In another example, the source region has P-type dopants, and the drain region has N-type dopants. In some embodiments, the source region or drain region of a transistor have the same semiconductor material, which may be the same as the channel material of the channel region.

A channel region may include one or more semiconductor materials with doping concentrations significantly smaller than those of the source region and the drain region. For example, in some embodiments, the channel material of the channel region may be an intrinsic (e.g., undoped) semiconductor material or alloy, not intentionally doped with any electrically active impurity. In alternate embodiments, nominal impurity dopant levels may be present within the channel material, for example to set a threshold voltage Vt, or to provide HALO pocket implants, etc. In such impurity-doped embodiments however, impurity dopant level within the channel material is still significantly lower than the dopant level in the source region and the drain region, for example below 10¹⁵ cm⁻³ or below 10¹³ cm⁻³. Depending on the context, the term “S/D terminal” may refer to a S/D region or a S/D contact or electrode of a transistor.

The channel region includes one or more channel materials. A channel material may be composed of semiconductor material systems including, for example, N-type or P-type materials systems. In some embodiments, the channel material may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material may include a compound semiconductor with a first sub-lattice of at least one element from Group Ill of the periodic table (e.g., Al, Ga, In), and a second sub-lattice of at least one element of group V of the periodic table (e.g., P, As, Sb). In some embodiments, the channel material may include a compound semiconductor with a first sub-lattice of at least one element from Group II of the periodic table (e.g., Zn, Cd, Hg), and a second sub-lattice of at least one element of Group IV of the periodic table (e.g., C, Si, Ge, Sn, Pb). In some embodiments, the channel material is an epitaxial semiconductor material deposited using an epitaxial deposition process. The epitaxial semiconductor material may have a polycrystalline structure with a grain size between about 2 nanometers and 100 nanometers, including all values and ranges therein.

For N-type transistors (e.g., the first transistor), the channel material may advantageously include a Ill-V material having a high electron mobility, such as, but not limited to InGaAs, InP, InSb, and InAs. For some such embodiments, the channel material may be a ternary Ill-V alloy, such as InGaAs, GaAsSb, InAsP, or InPSb. For some InxGa1-xAs fin embodiments, In content (x) may be between 0.6 and 0.9, and may advantageously be at least 0.7 (e.g., In0.7Ga0.3As). In some embodiments with highest mobility, the channel material may be an intrinsic Ill-V material, i.e., a Ill-V semiconductor material not intentionally doped with any electrically active impurity. In alternate embodiments, a nominal impurity dopant level may be present within the channel material, for example to further fine-tune a threshold voltage Vt, or to provide HALO pocket implants, etc. Even for impurity-doped embodiments however, impurity dopant level within the channel material 304 may be relatively low, for example below 10¹⁵ dopant atoms per cubic centimeter (cm⁻³), and advantageously below 10¹³ cm⁻³. These materials may be amorphous or polycrystalline, e.g., having a crystal grain size between 0.5 nanometers and 100 nanometers.

For P-type transistors (e.g., the second transistor), the channel material may advantageously be a Group IV material having a high hole mobility, such as, but not limited to Ge or a Ge-rich SiGe alloy. For some example embodiments, the channel material may have a Ge content between 0.6 and 0.9, and advantageously may be at least 0.7. In some embodiments with highest mobility, the channel material may be intrinsic Ill-V (or IV for P-type devices) material and not intentionally doped with any electrically active impurity. In alternate embodiments, one or more nominal impurity dopant levels may be present within the channel material, for example to further set a threshold voltage (Vt), or to provide HALO pocket implants, etc. Even for impurity-doped embodiments however, impurity dopant level within the channel portion is relatively low, for example below 10¹⁵ cm⁻³, and advantageously below 10¹³ cm⁻³. These materials may be amorphous or polycrystalline, e.g., having a crystal grain size between 0.5 nanometers and 100 nanometers.

In some embodiments, for a thin-film transistor (TFT), the channel material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, molybdenum disulfide, N- or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminum gallium nitride, indium phosphite, black phosphorus, zinc sulfide, indium sulfide, gallium sulfide, each of which may possibly be doped with one or more of gallium, indium, aluminum, fluorine, boron, phosphorus, arsenic, nitrogen, tantalum, tungsten, and magnesium, etc. In some embodiments, a thin-film channel material may be deposited at relatively low temperatures, which allows depositing the channel material within the thermal budgets imposed on back-end fabrication to avoid damaging other components, e.g., front end components such as logic devices.

The conductive structure 130 functions as gate electrodes of the first transistor and the second transistor. The conductive structure 130 includes one or more conductive materials, such as metal, polycrystalline silicon, other types of conductive materials, or some combination thereof. In some embodiments, the choice of the conductive materials in the conductive structure 130 may depend on whether the transistor is a P-type transistor or an N-type transistor. For a P-type transistor, gate electrode materials that may be used in different portions of the gate electrode may include, but are not limited to, Ru, palladium, platinum, Co, nickel, and conductive metal oxides (e.g., ruthenium oxide). For an N-type transistor, gate electrode materials that may be used in different portions of the gate electrode, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide).

In some embodiments, the conductive structure 130 may include a stack of a plurality of gate electrode materials, where zero or more materials of the stack are work function materials and at least one material of the stack is a fill metal layer. Further materials/layers may be included next to the gate electrode for other purposes, such as to act as a diffusion barrier layer or/and an adhesion layer. The conductive structure 130 may be electrically coupled to a power plane, ground plane, or signal plane for facilitating power supply or signal transmission for the first transistor and the second transistor.

The IC device 100 may also include an electrode over each source region. The electrode may be referred to as a source electrode or source contact. The IC device 100 may also include an electrode over each drain region. The electrode may be referred to as a drain electrode or drain contact. Each electrode is electrically conductive and may be coupled to the corresponding source or drain terminal, e.g., for receiving power. Each electrode may include one or more electrically conductive materials, such as metals. Examples of metals in the electrode and the electrode may include, but are not limited to, ruthenium (Ru), copper (Cu), cobalt (Co), palladium (Pd), platinum (Pt), nickel (Ni), and so on.

The insulator layer 140 is over the device region 150. A portion of the insulator layer 140 may be between the conductive structure 130 and the device region 150. The insulator layer 140 includes one or more dielectric materials, such as oxide or other low-k dielectric materials. Example oxide in the dielectric layer may include silicon oxide (SiO), silicon oxycarbide (SiOC), silicon oxycarbonitride (SiOCN), and so on.

The device region 150 may be any suitable structure, such as a substrate, a die, a wafer, or a chip, based on which transistors can be built. The device region 150 may, e.g., be the wafer 2000 of FIG. 11A, discussed below, and may be, or be included in, a die, e.g., the singulated die 2002 of FIG. 11B, discussed below. In some embodiments, the device region 150 may be a semiconductor substrate composed of semiconductor material systems including, for example, N-type or P-type materials systems. In some embodiments, the semiconductor substrate may be a crystalline substrate formed using a bulk silicon or a silicon-on-insulator substructure. In other embodiments, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of Group Ill-V, Group II-VI, or Group IV materials. In some embodiments, the substrate may be non-crystalline. In some embodiments, the support structure may be a printed circuit board (PCB) substrate. One or more transistors, such as the transistor may be built on the device region 150.

Although a few examples of materials from which the device region 150 may be formed are described here, any material that may serve as a foundation upon which an IC may be built falls within the spirit and scope of the present disclosure. In various embodiments, the device region 150 may include any such substrate, possibly with some layers and/or devices already formed thereon, not specifically shown in the present figures. In some embodiments, the device region 150 may be a support structure. As used herein, the term “support” does not necessarily mean that it provides mechanical support for the IC devices/structures (e.g., transistors, capacitors, interconnects, and so on) built thereon. For example, some other structure (e.g., a carrier substrate or a package substrate) may provide such mechanical support and the device region 150 may provide material “support” in that, e.g., the IC devices/structures described herein are build based on the semiconductor materials of the device region 150. However, in some embodiments, the device region 150 may provide mechanical support.

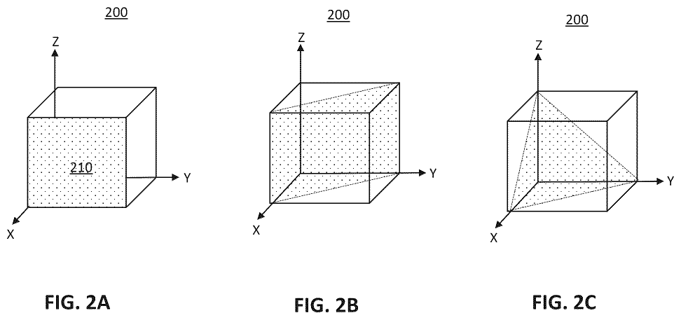

FIGS. 2A-2C illustrate lattice planes 210, 220, and 230 in an example crystal structure 200, according to some embodiments of the disclosure. The crystal structure 200 may be an ordered arrangement of atoms, ions, or molecules in a crystalline material, such as a crystalline semiconductor material. For the purpose of illustration and simplicity, the crystal structure 200 is a cube in a three-dimensional space having X, Y, and Z axes. In other embodiments, the crystal structure 200 may have a different shape, such as hexagonal, tetragonal, monoclinic, and so on. In some embodiments, the crystal structure 200 may be a unit cell of a larger crystal structure. The unit cell may include the smallest group of particles that constitutes the repeating pattern in the crystalline material. The crystal structure 200 may have a plurality of lattice plane, including the lattice plane 210 highlighted in FIG. 2A, the lattice plane 220 highlighted in FIG. 2B, and the lattice plane 230 highlighted in FIG. 2C. A lattice plane may be a plane containing at least three noncollinear crystal lattice points. A lattice plane may have periodic intersections with the crystal lattice. A lattice plane may have Miller indices that include three values. Miller indices form a notation system in crystallography for lattice planes in crystal (Bravais) lattices.

As shown in FIG. 2A, the lattice plane 210 is perpendicular to the X axis. The Miller indices of the lattice plane 210 is (100). The lattice plane 210 corresponds to the crystal direction with Miller indices [100]. The lattice plane 220 in FIG. 2B is perpendicular to the X axis. The Miller indices of the lattice plane 220 is (110). The lattice plane 220 corresponds to the crystal direction with Miller indices [110]. The lattice plane 230 in FIG. 2C is perpendicular to the X axis. The Miller indices of the lattice plane 230 is (111). The lattice plane 230 corresponds to the crystal direction with Miller indices [111]. The lattice planes 210, 220, and 230 may have different arrangement of particles of the semiconductor material. The mobility of charge carriers in the lattice planes 210, 220, and 230 can be different.

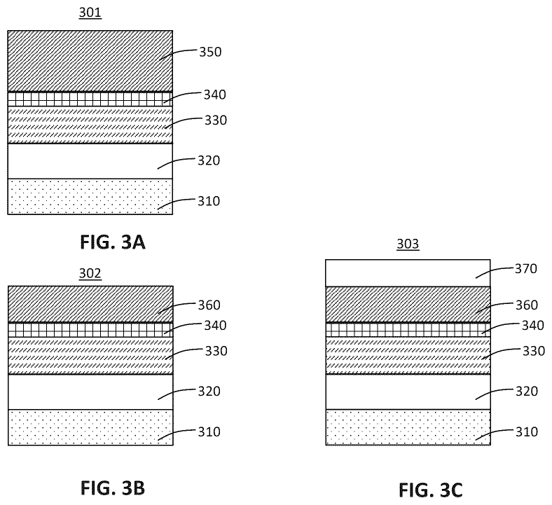

FIGS. 3A-3C illustrate an example process of forming semiconductor structures 330 and 360 with [111] crystal direction, according to some embodiments of the disclosure. In FIG. 3A, a layered structure 301 is formed. The layered structure 301 includes a support structure 310, an insulator layer 320, a semiconductor structure 330, a dielectric layer 340, and another semiconductor structure 350, which are stacked over each other. The support structure 310 may be any suitable structure, such as a substrate, a die, a wafer, or a chip, based on which semiconductor structures 330 and 350 can be built. The support structure 310 may be the same or similar as the device region 150 in FIG. 1. In some embodiments, the support structure 310 is a semiconductor substrate, such as a Si substrate. The insulator layer 320 is over various portions of the support structure 310. The insulator layer 320 may include one or more electrical insulators, such as a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, and so on.

In some embodiments, the semiconductor structures 330 and 350 may each be formed using an epitaxial process. The semiconductor structures 330 and 350 may both have crystal structures. In some embodiments, the semiconductor structures 330 and 350 may both be formed on the same lattice plane, such as the lattice plane (111). For instance, the top or bottom surface of each of the semiconductor structures 330 and 350 may be on the lattice plane (111). The semiconductor structures 330 and 350 may have different semiconductor materials. In an example, the semiconductor structure 330 may include Si, while the semiconductor structure 350 may include Ge. In other examples, the material of the semiconductor structure 330 or the semiconductor structure 350 may be a different material. The semiconductor structure 350 may be doped with N-type dopants. In some embodiments, the semiconductor structure 350 can be used as a semiconductor structure of a N-type transistor.

The dielectric layer 340 is between the semiconductor structure 330 and the semiconductor structure 350. The dielectric layer 340 includes one or more dielectric materials. In some embodiments, the dielectric layer 340 may be formed by depositing a dielectric material (e.g., a nitride) over the semiconductor structure 330. In some embodiments, the dielectric layer 340 may be a liner or hard mask.

In FIG. 3B, the semiconductor structure 350 is thinned, which forms a semiconductor structure 360. The layered structure 301 becomes a layered structure 302. In some embodiments, thinning the semiconductor structure 350 can remove one or more defective portions of the semiconductor structure 350. The semiconductor structure 350 may be thinned through planarization, etch, other thinning methods, or some combination thereof.

In FIG. 3C, an oxide layer 370 is formed over the semiconductor structure 360. The layered structure 302 becomes a layered structure 303. The layered structure 303 may be used to form a CMOS circuit with heterogeneous orientation.

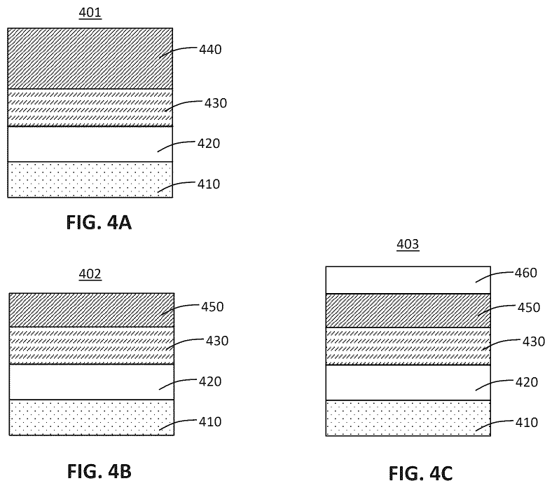

FIGS. 4A-4C illustrate an example process of forming semiconductor structures 430 and 450 with [100] crystal direction, according to some embodiments of the disclosure. In FIG. 4A, a layered structure 401 is formed. The layered structure 401 includes a support structure 410, an insulator layer 420, a semiconductor structure 430, and another semiconductor structure 440, which are stacked over each other. The support structure 410 may be any suitable structure, such as a substrate, a die, a wafer, or a chip, based on which semiconductor structures 430 and 440 can be built. The support structure 410 may be the same or similar as the device region 150 in FIG. 1. In some embodiments, the support structure 410 is a semiconductor substrate, such as a Si substrate. The insulator layer 420 is over various portions of the support structure 410. The insulator layer 420 may include one or more electrical insulators, such as a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, and so on.

In some embodiments, the semiconductor structures 430 and 440 may be formed using one or more epitaxial processes. The semiconductor structure 440 is formed on top of the semiconductor structure 430. The semiconductor structures 430 and 440 may both have crystal structures. In some embodiments, the semiconductor structures 430 and 440 may both be formed on the same lattice plane, such as the lattice plane (100). For instance, the top or bottom surface of each of the semiconductor structures 430 and 440 may be on the lattice plane (100). The semiconductor structures 430 and 440 may have different semiconductor materials. In an example, the semiconductor structure 430 may include Si, while the semiconductor structure 440 may include Ge. In other examples, the material of the semiconductor structure 430 or the semiconductor structure 440 may be a different material. The semiconductor structure 440 may be doped with P-type dopants. In some embodiments, the semiconductor structure 440 can be used as a semiconductor structure of a P-type transistor.

In FIG. 4B, the semiconductor structure 440 is thinned, which forms a semiconductor structure 450. The layered structure 401 becomes a layered structure 402. In some embodiments, thinning the semiconductor structure 440 can remove one or more defective portions of the semiconductor structure 440. The semiconductor structure 440 may be thinned through planarization, etch, other thinning methods, or some combination thereof.

In FIG. 4C, an oxide layer 460 is formed over the semiconductor structure 450. In some embodiments, the oxide layer 460 may include the same oxide as the oxide layer 370 in FIG. 3C. The layered structure 402 becomes a layered structure 403. The layered structure 403 may be used to form a CMOS circuit with heterogeneous orientation.

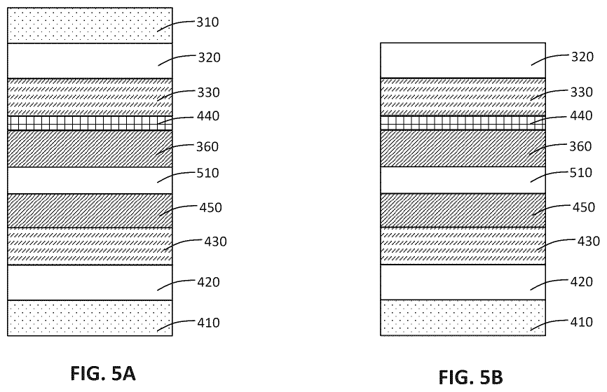

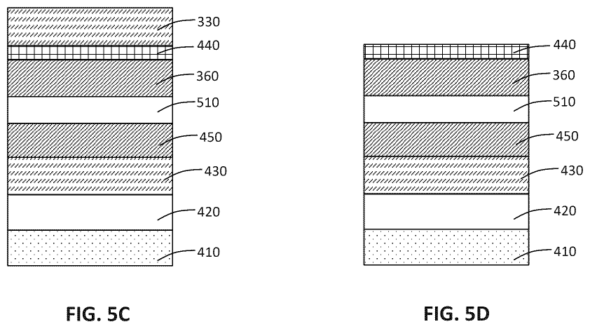

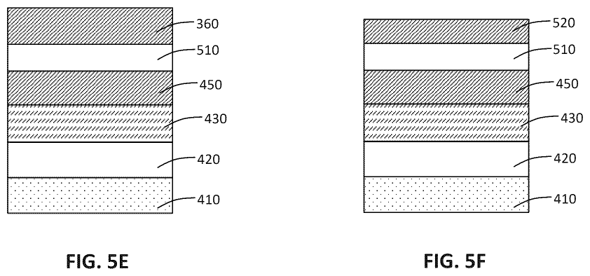

FIGS. 5A-5F illustrate an example process of stacking semiconductor structures 520 and 450 with heterogeneous orientation, according to some embodiments of the disclosure. The process may be used to fabricate IC devices with CMOS circuits, such as the IC devices 100, 700, 705, or 800. The process may be performed after the process in FIGS. 3A-3C and the process in FIGS. 4A-4C are complete.

In FIG. 5A, the layered structure 303 and the layered structure 403 are coupled so that the semiconductor structure 360 and the semiconductor structure 450 are coupled. In some embodiments, the layered structure 303 is bonded with the layered structure 403, e.g., through an oxide layer 510. The layered structure 303 may have been flipped upside down so that the layered structure 303 and the layered structure 403 can be bonded together through the oxide layers 370 and 460. The oxide layer 510 may include at least part of the oxide layer 370 and at least part of the oxide layer 460. The oxide layer 510 is between the semiconductor structure 360 and the semiconductor structure 450. In some embodiments, the oxide layer 510 enables the semiconductor structure 360 and the semiconductor structure 450 to be physically attached to each other, and the oxide layer 510 is between the semiconductor structure 360 and the semiconductor structure 450. As described above, the semiconductor structure 360 may have a surface in the lattice plane (111), while the semiconductor structure 450 may have a surface in the lattice plane (100). Also, the semiconductor structure 360 and the semiconductor structure 450 are doped with opposite types of dopants. In an example, the semiconductor structure 360 is doped with N-type dopants, while the semiconductor structure 450 is doped with P-type dopants.

In FIG. 5B, the support structure 310 is removed. In FIG. 5C, the insulator layer 320 is removed. In FIG. 5D, the semiconductor structure 330 is removed. In FIG. 5E, the dielectric layer 340 is removed. The support structure 310, insulator layer 320, semiconductor structure 330, and dielectric layer 340 may be removed in a single removal process or in multiple removal processes. The removal process may include etching or other types of material removal methods. After the dielectric layer 340 is removed, the semiconductor structure 360 is exposed.

In FIG. 5F, the semiconductor structure 360 is further thinned to form a semiconductor structure 520. The semiconductor structure 520 is separated from the semiconductor structure 450 by the oxide layer 510. The semiconductor structure 520 may be an example of the semiconductor structure 110 in FIG. 1. The semiconductor structure 450 may be an example of the semiconductor structure 120 in FIG. 1.

Even though FIGS. 3A-3C, 4A-4C, and 5A-5F show processes for forming a pair of semiconductor structures 520 and 450 that have heterogeneous orientation. The processes may be used to form multiple pairs of semiconductor structures with heterogeneous orientation. For instance, the processes may be used for form multiple semiconductor structures, each of which is the same or similar as the semiconductor structure 520, and additional semiconductor structures, each of which is the same or similar as the semiconductor structure 450. Also, the processes may be used to form semiconductor structures of different shapes. The process may be used to form IC devices including semiconductor structures with heterogeneous orientation, such as the IC devices 100, 700, 705, and 800.

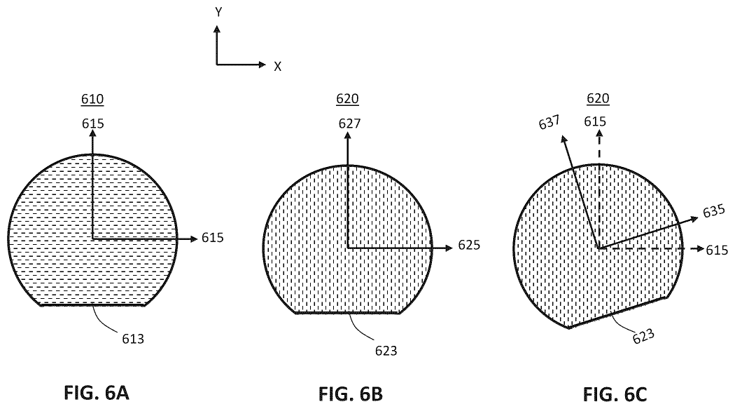

FIGS. 6A-6C illustrate an example pair of unaligned wafers 610 and 620, according to some embodiments of the disclosure. FIG. 6A shows a cross-section view of a wafer 610 in a X-Y plane. The wafer 610 has a flat 613 that can provide a visual reference to the orientation of the wafer 610. The flat 613 is a straight line in the X-Y plane. The flat 613 may have other shapes in other embodiments. In some embodiments, the wafer 610 may have multiple flats, the flat 613 may be the primary flat, e.g., the longest flat. FIG. 6A illustrates two orientations 615 and 617 of the wafer 610. The orientation 615 is parallel to the flat 613. The orientation 617 is orthogonal to the flat 613. The wafer 610 may be an example of the device region 150 in FIG. 1.

FIG. 6B shows a cross-section view of another wafer 620. In some embodiments, the wafer 620 has the same size or material as the wafer 610. In other embodiments, the wafer 620 has a different size or material from the wafer 610. For example, the wafer 620 may have a smaller cross-section in the X-Y plane than the wafer 610 or a shorter thickness in a Z-axis, which is perpendicular to the X-Y plane, than the wafer 620. The wafer 620 has a flat 623 that can provide a visual reference to the orientation of the wafer 620. FIG. 6B illustrates two orientations 625 and 627 of the wafer 620. The orientation 625 is parallel to the flat 623. The orientation 627 is orthogonal to the flat 623. As shown in FIG. 6B, the orientation 625 is aligned with the orientation 615, and the orientation 627 is aligned with the orientation 617. Thus, the wafers 610 and 620 have aligned orientations. The wafer 620 may be another example of the device region 150 in FIG. 1.

In FIG. 6C, the wafer 620 is rotated. Accordingly, the flat 623 is rotated. The wafer 620 has new orientations 635 and 637, which are not aligned with the orientations 615 and 617 of the wafer 610 anymore. The angle between the orientations 635 and 615 and the angle between the orientations 637 and 617 can be in a range from 4 to 60 degrees. In some embodiments, the angle is approximately 54.7 degrees. Even though not shown in FIGS. 6A-6C, semiconductor structures may be formed based on the wafers 610 and 620. In some embodiments, the semiconductor structures may have the same semiconductor material. By rotating the wafter 620, the semiconductor structures may get different orientations. For instance, a surface of a semiconductor structure formed based on the wafer 610 may be on the lattice plane (100). A surface of a semiconductor structure formed based on the wafer 620 may also be on the lattice plane (100) before rotation. After the wafter 620 is rotated, the semiconductor structure formed based on the wafer 620 may have a surface on the lattice plane (111). In the embodiment of FIG. 6C, the wafer 620 is rotated. In other embodiments, the wafer 610 may be rotated instead. After the rotation, the two wafers 620 may be bonded to form IC devices including semiconductor structures with heterogeneous orientation, such as the IC devices 100, 700, 705, and 800.

FIG. 7A is a perspective view of an example IC device 700 including nanoribbon-shaped semiconductor structures 710 and 720 with heterogeneous orientation, according to some embodiments of the disclosure. The semiconductor structures 710 are individually referred to as semiconductor structure 710. The semiconductor structures 720 are individually referred to as semiconductor structure 720. The IC device 700 also includes a conductive structure 730, an insulator layer 740, and a device region 750. In other embodiments, the IC device 700 may include fewer, more, or different components. For example, the IC device 700 may include a different number of semiconductor structures, conductive structures, insulator layers, support structures, and so on. As another example, the IC device 700 may include semiconductor structures of different shapes.

The semiconductor structures 710 are stacked over each other. The semiconductor structures 710 include the source region, channel region, and drain region of a first transistor in the IC device 700. The portion of each semiconductor structure 710 that is wrapped around by the conductive structure 730 may form the channel region of the first transistor. The other two portions of each of the semiconductor structures 710 may form the source region and drain region, respectively. The first transistor also includes a gate, which may include at least part of the conductive structure 730. In some embodiments, at least part of the conductive structure 730 constitutes a gate electrode of the first transistor. The first transistor may include a gate insulator (not shown in FIG. 7A) that is between the gate electrode and the channel region.

The semiconductor structures 720 are stacked over each other. The semiconductor structures 720 include the source region, channel region, and drain region of a second transistor in the IC device 700. The portion of each semiconductor structure 720 that is wrapped around by the conductive structure 730 may form the channel region of the first transistor. The other two portions of each of the semiconductor structures 720 may form the source region and drain region, respectively. The second transistor also includes a gate, which may include at least part of the conductive structure 730. In some embodiments, at least part of the conductive structure 730 constitutes a gate electrode of the second transistor. The second transistor may include a gate insulator (not shown in FIG. 7A) that is between the gate electrode and the channel region.

The first transistor and the second transistor constitute at least part of a CMOS circuit in the IC device 700. In some embodiments, the first transistor may be an N-type transistor. For instance, the first transistor is an NMOS transistor. The second transistor may be a P-type transistor. For instance, the second transistor is an NMOS transistor. The first transistor may have electrons as charge carriers, while the second transistor may have holes as charge carriers. To gain a symmetric performance of the CMOS circuit, the semiconductor structures 710 and the semiconductor structures 720 may have different crystal directions. For instance, at least a portion of each semiconductor structure 710 may be in the (111) lattice plane of the crystal structure of the semiconductor material in the semiconductor structures 710. The crystal direction of each semiconductor structure 710 is [111]. At least a portion of each semiconductor structure 720 may be in the (100) lattice plane of the crystal structure of the semiconductor material in the semiconductor structures 720. The crystal direction of each semiconductor structure 720 is [100]. In some embodiments, the semiconductor material in the semiconductor structures 710 and the semiconductor material in the semiconductor structures 720 may be the same semiconductor material. Examples of the semiconductor material include Ge, InGaAs, GaAs, InAs, SiGe, GaN, other proper materials, or some combination thereof.

In the embodiments of FIG. 7A, a surface 760 of each semiconductor structure 710 may be in the (111) plane, and a surface 770 of each semiconductor structure 720 may be in the (111) plane. The surface 760 is in parallel with the surface 770. Even though the surface 760 and the surface 770 are each the top surface of the corresponding semiconductor structure in FIG. 7A, the surface 760 or 770 may be a side surface or the bottom surface of the corresponding semiconductor structure in some embodiments. Also, the surface 760 may be perpendicular to the surface 770 in some embodiments. For example, the surface 760 may be the top or bottom surface, while the surface 770 may be a side surface. As another example, the surface 770 may be the top or bottom surface, while the surface 760 may be a side surface.

The first transistor or the second transistor may be a FET, such as metal-oxide-semiconductor FET (MOSFET), tunnel FET (TFET), GAA transistor, other types of FET, or a combination of both. The semiconductor structures 710 and semiconductor structures 720 may each be a non-planar structure. A non-planar structure is a three-dimensional structure, such as fin, nanowire, or nanoribbon. A non-planar structure may have a longitudinal axis and a transvers cross-section perpendicular to the longitudinal axis. In some embodiments, a dimension of the non-planar structure along the longitudinal axis may be greater than dimensions along other directions, e.g., directions along axes perpendicular to the longitudinal axis. In the embodiments of FIG. 7A, the semiconductor structures 710 and semiconductor structures 720 are nanoribbons. In other embodiments, the semiconductor structures 710 or semiconductor structures 720 may have a different shape, such as nanowire. A nanowire may have circular cross-section, while the semiconductor structures 710 and semiconductor structures 720 in FIG. 7A have rectangular cross-sections. Also, the number of nanoribbons in the first transistor or the second transistor may be different.

As described above, the semiconductor structures 710 and semiconductor structures 720 provide the channel regions, source regions, and drain regions of the two transistors, respectively. In each transistor, the source region and the drain region may be connected to the channel region. The source region and the drain region each include a semiconductor material (such as the semiconductor materials of source and drain regions described above) with dopants. The channel region may include a channel material, such as the channel materials described above.

The conductive structure 730 functions as gate electrodes of the first transistor and the second transistor. The conductive structure 730 includes one or more conductive materials, such as metal, polycrystalline silicon, other types of conductive materials, or some combination thereof. In some embodiments, the conductive structure 730 may be the same or similar as the conductive structure 130 in FIG. 1. The conductive structure 730 may be electrically coupled to a power plane, ground plane, or signal plane for facilitating power supply or signal transmission for the first transistor and the second transistor.

The IC device 700 may also include an electrode over each source region. The electrode may be referred to as a source electrode or source contact. The IC device 700 may also include an electrode over each drain region. The electrode may be referred to as a drain electrode or drain contact. Each electrode is electrically conductive and may be coupled to the corresponding source or drain terminal, e.g., for receiving power. Each electrode may include one or more electrically conductive materials, such as the electrically conductive materials described above.

The insulator layer 740 is over the device region 750. A portion of the insulator layer 740 may be between the conductive structure 730 and the device region 750. The insulator layer 740 includes one or more dielectric materials, such as the dielectric materials described above. The device region 750 may be any suitable structure, such as a substrate, a die, a wafer, or a chip, based on which transistors can be built. In some embodiments, the device region 750 may be an example of the wafer 610 in FIG. 6A, the wafer 620 in FIG. 6C, or the wafer 2000 in FIG. 11A. In other embodiments, the device region 750 may be, or be included in, a die, e.g., the singulated die 2002 of FIG. 11B. In some embodiments, the device region 750 may be the same or similar as the device region 150.

FIG. 7B is a perspective view of an example IC device 705 including fin-shaped semiconductor structure 715 and 725 with heterogeneous orientation, according to some embodiments of the disclosure. The IC device 705 also includes a conductive structure 735, an insulator layer 745, and a device region 755. In other embodiments, the IC device 705 may include fewer, more, or different components. For example, the IC device 705 may include a different number of semiconductor structures, conductive structures, insulator layers, support structures, and so on. As another example, the IC device 705 may include semiconductor structures of different shapes.

The semiconductor structure 715 includes the source region, channel region, and drain region of a first transistor in the IC device 705. The portion of the semiconductor structure 715 that is wrapped around by the conductive structure 735 may be the channel region of the first transistor. The other portions of the semiconductor structure 715 may be the source region and drain region, respectively. The first transistor also includes a gate, which may include at least part of the conductive structure 735. In some embodiments, at least part of the conductive structure 735 constitutes a gate electrode of the first transistor. The first transistor may include a gate insulator (not shown in FIG. 7B) that is between the gate electrode and the channel region.

The semiconductor structure 725 includes the source region, channel region, and drain region of a second transistor in the IC device 705. The portion of the semiconductor structure 725 that is wrapped around by the conductive structure 735 may be the channel region of the second transistor. The other portions of the semiconductor structure 725 may be the source region and drain region, respectively. The second transistor also includes a gate, which may include at least part of the conductive structure 735. In some embodiments, at least part of the conductive structure 735 constitutes a gate electrode of the second transistor. The second transistor may include a gate insulator (not shown in FIG. 7B) that is between the gate electrode and the channel region.

The first transistor and the second transistor constitute at least part of a CMOS circuit in the IC device 705. In some embodiments, the first transistor may be an N-type transistor. For instance, the first transistor is an NMOS transistor. The second transistor may be a P-type transistor. For instance, the second transistor is an NMOS transistor. The first transistor may have electrons as charge carriers, while the second transistor may have holes as charge carriers. To gain a symmetric performance of the CMOS circuit, the semiconductor structure 715 and the semiconductor structure 725 may have different crystal directions. For instance, at least a portion of the semiconductor structure 715 may be in the (111) lattice plane of the crystal structure of the semiconductor material in the semiconductor structure 715. The crystal direction of the semiconductor structure 715 is [111]. At least a portion of the semiconductor structure 725 may be in the (100) lattice plane of the crystal structure of the semiconductor material in the semiconductor structure 725. The crystal direction of the semiconductor structure 725 is [100]. In some embodiments, the semiconductor material in the semiconductor structure 715 and the semiconductor material in the semiconductor structure 725 may be the same semiconductor material. Examples of the semiconductor material include Ge, InGaAs, GaAs, InAs, SiGe, GaN, other proper materials, or some combination thereof.

In the embodiments of FIG. 7B, a surface 765 of the semiconductor structure 715 may be in the (111) plane, and a surface 775 of the semiconductor structure 725 may be in the (111) plane. The surface 765 is in parallel with the surface 775. Even though the surface 765 and the surface 775 are each the left-side surface of the corresponding semiconductor structure in FIG. 7B, the surface 765 or 775 may be the right-side side surface, the top surface, or the bottom surface of the corresponding semiconductor structure in other embodiments. Also, the surface 765 may be perpendicular to the surface 775 in other embodiments.

The first transistor or the second transistor may be a FET, such as metal-oxide-semiconductor FET (MOSFET), tunnel FET (TFET), GAA transistor, other types of FET, or a combination of both. The semiconductor structure 715 and semiconductor structure 725 may each be a non-planar structure. A non-planar structure is a three-dimensional structure, such as fin, nanowire, or nanoribbon. A non-planar structure may have a longitudinal axis and a transvers cross-section perpendicular to the longitudinal axis. In some embodiments, a dimension of the non-planar structure along the longitudinal axis may be greater than dimensions along other directions, e.g., directions along axes perpendicular to the longitudinal axis. In the embodiments of FIG. 7B, the semiconductor structure 715 and semiconductor structure 725 are both fins. In other embodiments, the semiconductor structure 715 or semiconductor structure 725 may have a different shape.

As described above, the semiconductor structure 715 and semiconductor structure 725 provides the channel regions, source regions, and drain regions of the two transistors, respectively. In each transistor, the source region and the drain region may be connected to the channel region. The source region and the drain region each include a semiconductor material (such as the semiconductor materials of source and drain regions described above) with dopants. The channel region may include a channel material, such as the channel materials described above.

The conductive structure 735 functions as gate electrodes of the first transistor and the second transistor. The conductive structure 735 includes one or more conductive materials, such as metal, polycrystalline silicon, other types of conductive materials, or some combination thereof. In some embodiments, the conductive structure 735 may be the same or similar as the conductive structure 130 in FIG. 1. The conductive structure 735 may be electrically coupled to a power plane, ground plane, or signal plane for facilitating power supply or signal transmission for the first transistor and the second transistor.

The IC device 705 may also include an electrode over each source region. The electrode may be referred to as a source electrode or source contact. The IC device 705 may also include an electrode over each drain region. The electrode may be referred to as a drain electrode or drain contact. Each electrode is electrically conductive and may be coupled to the corresponding source or drain terminal, e.g., for receiving power. Each electrode may include one or more electrically conductive materials, such as the electrically conductive materials described above.

The insulator layer 745 is over the device region 755. A portion of the insulator layer 745 may be between the conductive structure 735 and the device region 755. The insulator layer 745 includes one or more dielectric materials, such as the dielectric materials described above. The device region 755 may be any suitable structure, such as a substrate, a die, a wafer, or a chip, based on which transistors can be built. In some embodiments, the device region 755 may be an example of the wafer 610 in FIG. 6A, the wafer 620 in FIG. 6C, or the wafer 2000 in FIG. 11A. In other embodiments, the device region 755 may be, or be included in, a die, e.g., the singulated die 2002 of FIG. 11B. In some embodiments, the device region 755 may be the same or similar as the device region 150.

FIG. 8 is a perspective view of an example IC device 800 including semiconductor structures 810 and 820 with heterogeneous orientation and heterogeneous shape, according to some embodiments of the disclosure. The semiconductor structures 820 are individually referred to as semiconductor structure 820. The IC device 800 also includes a conductive structure 830, an insulator layer 840, and a device region 850. In other embodiments, the IC device 800 may include fewer, more, or different components. For example, the IC device 800 may include a different number of semiconductor structures, conductive structures, insulator layers, support structures, and so on. As another example, the IC device 800 may include semiconductor structures of different shapes.

The semiconductor structure 810 may include the source region, channel region, and drain region of a first transistor in the IC device 800. The portion of the semiconductor structure 810 that is wrapped around by the conductive structure 830 may form the channel region of the first transistor. The other two portions of the semiconductor structure 810 may form the source region and drain region, respectively. The first transistor also includes a gate, which may include at least part of the conductive structure 830. In some embodiments, at least part of the conductive structure 830 constitutes a gate electrode of the first transistor. The first transistor may include a gate insulator (not shown in FIG. 8) that is between the gate electrode and the channel region.

The semiconductor structures 820 are stacked over each other. The semiconductor structures 820 include the source region, channel region, and drain region of a second transistor in the IC device 800. The portion of each semiconductor structure 820 that is wrapped around by the conductive structure 830 may form the channel region of the first transistor. The other two portions of each of the semiconductor structures 820 may form the source region and drain region, respectively. The second transistor also includes a gate, which may include at least part of the conductive structure 830. In some embodiments, at least part of the conductive structure 830 constitutes a gate electrode of the second transistor. The second transistor may include a gate insulator (not shown in FIG. 8) that is between the gate electrode and the channel region.

The first transistor and the second transistor constitute at least part of a CMOS circuit in the IC device 800. In some embodiments, the first transistor may be an N-type transistor. For instance, the first transistor is an NMOS transistor. The second transistor may be a P-type transistor. For instance, the second transistor is an NMOS transistor. The first transistor may have electrons as charge carriers, while the second transistor may have holes as charge carriers. To gain a symmetric performance of the CMOS circuit, the semiconductor structure 810 and the semiconductor structures 820 may have different crystal directions. For instance, at least a portion of the semiconductor structure 810 may be in the (111) lattice plane of the crystal structure of the semiconductor material in the semiconductor structure 810. The crystal direction of the semiconductor structure 810 is [111]. At least a portion of each semiconductor structure 820 may be in the (100) lattice plane of the crystal structure of the semiconductor material in the semiconductor structures 820. The crystal direction of each semiconductor structure 820 may be [100]. In some embodiments, the semiconductor material in the semiconductor structure 810 and the semiconductor material in the semiconductor structures 820 may be the same semiconductor material. Examples of the semiconductor material include Ge, InGaAs, GaAs, InAs, SiGe, GaN, other proper materials, or some combination thereof.

In the embodiments of FIG. 8, a surface 815 of the semiconductor structure 810 may be in the (111) plane, and a surface 825 of each semiconductor structure 820 may be in the (111) plane. The surface 815 is perpendicular to the surface 825. Even though the surface 815 is the left-side surface of the semiconductor structure 810 in FIG. 8, the surface 815 may be the right-side surface in other embodiments. Even though the surface 825 is the top surface of the semiconductor structure 820 in FIG. 8, the surface 825 may be the bottom surface in other embodiments. Also, the surface 815 may be parallel with the surface 825 in other embodiments.

The first transistor or the second transistor may be a FET, such as metal-oxide-semiconductor FET (MOSFET), tunnel FET (TFET), GAA transistor, other types of FET, or a combination of both. The semiconductor structure 810 and semiconductor structures 820 may each be a non-planar structure. A non-planar structure is a three-dimensional structure, such as fin, nanowire, or nanoribbon. A non-planar structure may have a longitudinal axis and a transvers cross-section perpendicular to the longitudinal axis. In some embodiments, a dimension of the non-planar structure along the longitudinal axis may be greater than dimensions along other directions, e.g., directions along axes perpendicular to the longitudinal axis. In the embodiments of FIG. 8, the semiconductor structure 810 is a fin, while the semiconductor structures 820 are nanoribbons. In other embodiments, the semiconductor structure 810 or semiconductor structures 820 may have a different shape.

As described above, the semiconductor structure 810 and semiconductor structures 820 provide the channel regions, source regions, and drain regions of the two transistors, respectively. In each transistor, the source region and the drain region may be connected to the channel region. The source region and the drain region each include a semiconductor material (such as the semiconductor materials of source and drain regions described above) with dopants. The channel region may include a channel material, such as the channel materials described above.

The conductive structure 830 functions as gate electrodes of the first transistor and the second transistor. The conductive structure 830 includes one or more conductive materials, such as metal, polycrystalline silicon, other types of conductive materials, or some combination thereof. In some embodiments, the conductive structure 830 may be the same or similar as the conductive structure 130 in FIG. 1. The conductive structure 830 may be electrically coupled to a power plane, ground plane, or signal plane for facilitating power supply or signal transmission for the first transistor and the second transistor.

The IC device 800 may also include an electrode over each source region. The electrode may be referred to as a source electrode or source contact. The IC device 800 may also include an electrode over each drain region. The electrode may be referred to as a drain electrode or drain contact. Each electrode is electrically conductive and may be coupled to the corresponding source or drain terminal, e.g., for receiving power. Each electrode may include one or more electrically conductive materials, such as the electrically conductive materials described above.

The insulator layer 840 is over the device region 850. A portion of the insulator layer 840 may be between the conductive structure 830 and the device region 850. The insulator layer 840 includes one or more dielectric materials, such as the dielectric materials described above. The device region 850 may be any suitable structure, such as a substrate, a die, a wafer, or a chip, based on which transistors can be built. The device region 850 may, e.g., be the wafer 2000 of FIG. 11A, discussed below, and may be, or be included in, a die, e.g., the singulated die 2002 of FIG. 11B, discussed below. In some embodiments, the device region 850 may be the same or similar as the device region 150.

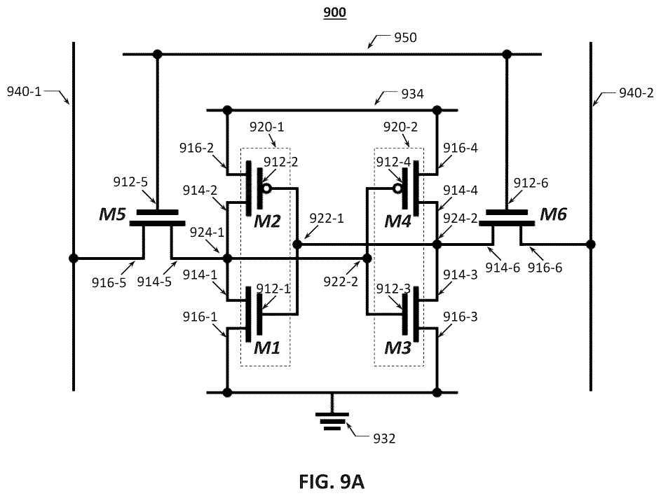

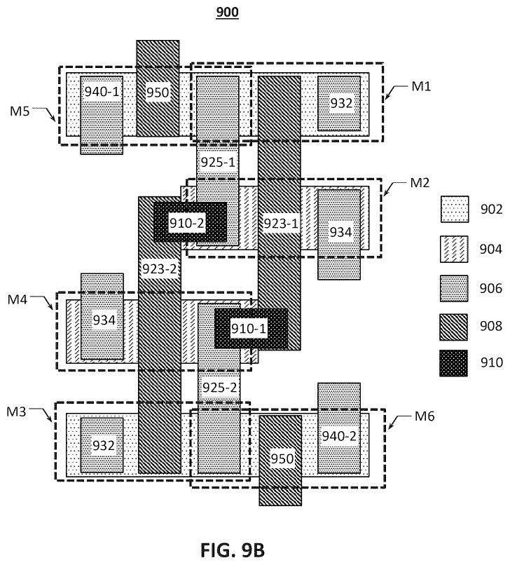

FIG. 9A is an electric circuit diagram of an example memory cell 900, according to some embodiments of the present disclosure. FIG. 9B provides a top-down plan view of one example implementation of the memory cell 900, according to some embodiments of the present disclosure. In some embodiments, the memory cell 900 may be an SRAM cell used in an SRAM array. As shown in FIG. 9B, the memory cell 900 includes transistors M1-M4 for storing a bit value or a memory state (e.g., logic “1” or “0”) of the cell, and two access transistors, M5 and M6, for controlling access to the cell (e.g., access to write information to the cell or access to read information from the memory cell 900). The memory cell 900 is a 6-transistor (6T) memory cell. In other embodiments, the memory cell 900 may include a different number of transistors. Each of the transistors M1-M6 may have any transistor architecture (e.g., planar or non-planar, fin, nanoribbon, nanowire, etc.). For example, the transistors M1-M6 may have the transistor architecture shown in FIGS. 1, 7A, 7B, and 8. An example of the transistors M1-M6 may be one of the transistors described above in conjunction with FIGS. 1, 7A, 7B, and 8.

In the memory cell 900, each bit may be stored on four transistors (M1, M2, M3, M4) that form two cross-coupled inverters 920, each having an input 922 and an output 924. The first inverter 920-1 may be formed by an NMOS transistor M1 and a PMOS transistor M2, while the second inverter 920-2 may be formed by an NMOS transistor M3 and a PMOS transistor M4. As shown in FIG. 9B, the gate stack 912-1 of the transistor M1 may be coupled to the gate stack 912-2 of the transistor M2, and both of these gate stacks may be coupled to the input 922-1 of the first inverter 920-1. On the other hand, the first S/D region 914-1 of the transistor M1 may be coupled to the first S/D region 914-2 of the transistor M2, and both of these first S/D regions 914-1 and 914-2 may be coupled to the output 924-1 of the first inverter 920-1. Similarly, for the second inverter 320-2, the gate stack 912-3 of the transistor M3 may be coupled to the gate stack 912-4 of the transistor M4, and both of these gate stacks may be coupled to the input 922-2 of the second inverter 920-2, while the first S/D region 914-3 of the transistor M3 may be coupled to the first S/D region 914-4 of the transistor M4, and both of these first S/D regions 914-3 and 914-4 may be coupled to the output 924-2 of the second inverter 920-2. As also shown in FIG. 9B, when the transistors M1 and M3 are NMOS transistors and when the transistors M2 and M4 are PMOS transistors as illustrated in FIG. 9B, the second S/D regions 916-1 and 916-3 of the transistors M1 and M3 may be coupled to a ground voltage 932, while the second S/D regions 916-2 and 916-4 of the transistors M2 and M4 may be coupled to a supply voltage 934, e.g., VDD. In the embodiments of the memory cell 900 where the NMOS transistors shown in FIG. 9B are replaced with PMOS transistors and vice versa, the designation of the ground voltage 932 and the supply voltage 934 would be reversed as well, all of which embodiments being within the scope of the present disclosure.

The four transistors M1-M4 in such configuration form a stable storage cell for storing a bit value of 0 or 1. As further shown in FIG. 9B, two additional access transistors, M5 and M6, may serve to control the access to the storage cell of the transistors M1-M4 during read and write operations. As shown in FIG. 9B, the first S/D region 914-5 of the access transistor M5 may be coupled to the output 924-1 of the first inverter 920-1. Phrased differently, the first S/D region 914-5 of the access transistor M5 may be coupled to each of the first S/D region 914-1 of the transistor M1 and the first S/D region 914-2 of the transistor M2. The second S/D region 916-5 of the access transistor M5 may be coupled to a first bitline 940-1. Thus, each of the first S/D region 914-1 of the transistor M1 and the first S/D region 914-2 of the transistor M2 may be coupled to the first bitline 940-1 (e.g., via the access transistor M5). The gate 912-5 of the access transistor M5 may be coupled to a wordline 950.

As further shown in FIG. 9B, the first S/D region 914-6 of the access transistor M6 may be coupled to the output 924-2 of the second inverter 920-2. Phrased differently, the first S/D region 914-6 of the access transistor M6 may be coupled to each of the first S/D region 914-3 of the transistor M3 and the first S/D region 914-4 of the transistor M4. The second S/D region 916-6 of the access transistor M6 may be coupled to a second bitline 940-2. Thus, each of the first S/D region 914-3 of the transistor M3 and the first S/D region 914-4 of the transistor M4 may be coupled to the second bitline 940-2 (e.g., via the access transistor M6). The gate 912-6 of the access transistor M6 may be coupled to the wordline 950. Thus, the gates 912-5 and 912-6 of both of the access transistors M5 and M6 may be coupled to a single, shared, WL, the wordline 950.

As also shown in FIG. 9B, the input 922-1 of the first inverter 920-1 may be coupled to the first S/D region 914-6 of the access transistor M6, while the input 922-2 of the second inverter 920-2 may be coupled to the first S/D region 914-5 of the access transistor M5. In other words, each of the gate stack 912-1 of the transistor M1 and the gate stack 912-2 of the transistor M2 may be coupled to the first S/D region 914-6 of the access transistor M6, while each of the gate stack 912-3 of the transistor M3 and the gate stack 912-4 of the transistor M4 may be coupled to the first S/D region 914-5 of the access transistor M5. Phrased differently, each of the gate stack 912-1 of the transistor M1 and the gate stack 912-2 of the transistor M2 may be coupled to the second bitline 940-2 (e.g., via the access transistor M6), while each of the gate stack 912-3 of the transistor M3 and the gate stack 912-4 of the transistor M4 may be coupled to the first bitline 940-1 (e.g., via the access transistor M5).

The wordline 950 and the first and second bitlines 940 may be used together to read and program (i.e., write to) the memory cell 900. In particular, access to the cell may be enabled by the wordline 950 which controls the two access transistors M5 and M6 which, in turn, control whether the memory cell 900 should be connected to the bitlines 940-1 and 940-2. During operation of the memory cell 900, a signal on the first bitline 940-1 may be complementary to a signal on the second bitline 940-2. The two bitlines 940 may be used to transfer data for both read and write operations. In other embodiments of the memory cell 900, only a single bitline 940 may be used, instead of two bitlines 940-1 and 940-2, although having one signal bitline and one inverse, such as the two bitlines 940, may help improve noise margins.

During read accesses, the bitlines 940 are actively driven high and low by the inverters 920 in the memory cell 900. This may improve SRAM bandwidth compared to DRAM. The symmetric structure of the memory cell 900 also allows for differential signaling, which may provide an improvement in detecting small voltage swings. Another difference with DRAM that may contribute to making SRAM faster than DRAM is that commercial chips accept all address bits at a time. By comparison, commodity DRAMs may have the address multiplexed in two halves, i.e. higher bits followed by lower bits, over the same package pins in order to keep their size and cost down.

Each of the wordline 950 and the bitlines 940, as well as intermediate elements coupling these lines to various terminals described herein, may be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

FIG. 9B provides a top-down plan view of one example implementation of a 6T memory cell, according to some embodiments of the present disclosure. FIG. 9B illustrates how the six transistors M1-M6 shown in FIG. 9B may be implemented. Several elements from FIG. 9B are labelled in FIG. 9B. For example, the transistors M1-M6 are labelled in FIG. 9B, with the approximate boundaries of the individual transistors shown in FIG. 9B with dashed rectangles. Certain elements, e.g., the specific S/D regions 914 and 916 and the gate stacks 912, are not labelled in FIG. 9B in order to not clutter the drawings.

FIG. 9B illustrates that transistors M1 and M5 may be provided along a first region of an N-type semiconductor 902, transistors M2 and M4 may each be provided along a respective first and second region of a P-type semiconductor 904, and the transistors M4 and M6 may be provided along a second region of the N-type semiconductor 902. Each of the regions of the N-type semiconductor 902 and P-type semiconductor 904 may be formed in a support structure (e.g., a substrate) or over a support structure, e.g., as a fin or nanoribbon. The N-type semiconductor 902 is suitable for forming transistors of a first type, e.g., NMOS transistors, while the P-type semiconductor 904 is suitable for forming transistors of a second type, e.g., PMOS transistors, thus realizing NMOS transistors M1, M3, M5, and M6, and PMOS transistors M2 and M4, as shown in FIG. 9B.

In the plan view shown in FIG. 9B, S/D contacts 906, gate electrodes 908, and interconnects 910 are formed over the N-type and P-type semiconductors 902 and 904, e.g., as layers processed over the N-type and P-type semiconductors 902 and 904. While not specifically shown in FIG. 9B, S/D regions may be formed under the S/D contacts 906, and gate dielectrics may be formed under the gate electrodes 908.

More specifically, a shared gate stack may be used to realize the gate stack 912-1 of the transistor M1 coupled to the gate stack 912-2 of the transistor M2. The shared gate stack is labelled 923-1 in FIG. 9B, representing a node that is the input 922-1 of the first inverter 920-1 of the memory cell 900. Similarly, a shared gate stack may be used to realize the gate stack 212-3 of the transistor M3 coupled to the gate stack 212-4 of the transistor M4 3. The shared gate stack is labelled 923-2 in FIG. 9B, representing a node that is the input 922-2 of the second inverter 920-2 of the memory cell 900.

As also shown in FIG. 9B, a first shared S/D contact may be used to realize the first S/D region 914-1 of the transistor M1 coupled to the first S/D region 914-2 of the transistor M2. The first shared S/D contact is labelled 925-1 in FIG. 9B, representing a node that is the output 924-1 of the first inverter 920-1 of the memory cell 900. Similarly, a second shared S/D contact may be used to realize the first S/D region 914-3 of the transistor M3 coupled to the first S/D region 914-4 of the transistor M4. The second shared S/D contact is labelled 925-2 in FIG. 9B, representing a node that is the output 924-2 of the second inverter 920-2 of the memory cell 900.

A first interconnect 910-1, shown in FIG. 9B, may then be used to couple the shared gate stack 923-1 of the first inverter 920-1 to the shared S/D contact 925-2 of the second inverter 920-2, thus realizing the coupling of the input 922-1 of the first inverter 920-1 to the output 924-2 of the second inverter 920-2, shown in FIG. 9B. Similarly, a second interconnect 910-2, shown in FIG. 9B, may then be used to couple the shared gate stack 923-2 of the second inverter 920-2 to the shared S/D contact 925-1 of the first inverter 920-1, thus realizing the coupling of the input 922-2 of the second inverter 920-2 to the output 924-1 of the first inverter 920-1, shown in FIG. 9B.

FIG. 9B further illustrates that, in a given memory cell 900, the first S/D region 914-5 of the transistor M5 may be shared with (e.g., be the same as) the first S/D region 914-1 of the transistor M1 (since both of these transistors are implemented in a single region of the N-type semiconductor 902). In addition, the first S/D region 914-3 of the transistor M3 may be shared with (e.g., be the same as) the first S/D region 914-6 of the transistor M6 (since both of these transistors are implemented in a single region of the N-type semiconductor 902).

Both of the second S/D region 916-1 of the transistor M1 and the second S/D region 916-3 of the transistor M3 may be coupled to the ground voltage 932, as was described with reference to FIG. 9B. Both of the second S/D region 916-2 of the transistor M2 and the second S/D region 916-4 of the transistor M4 may be coupled to the supply voltage 934, as was described with reference to FIG. 9B.

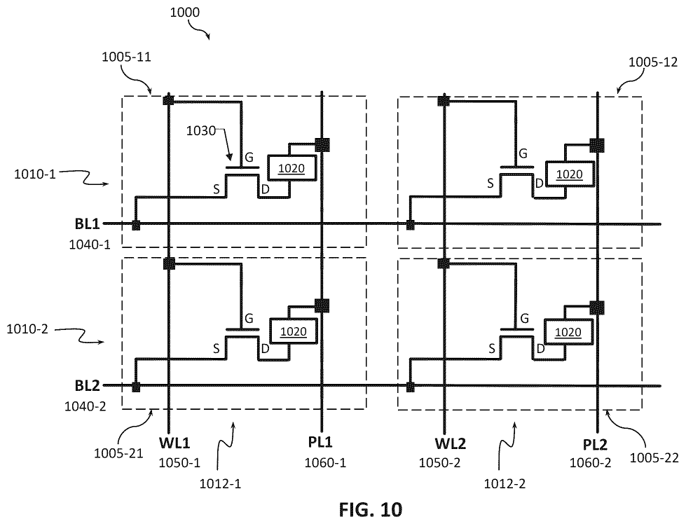

FIG. 10 is an electric circuit diagram of a memory array 1000, according to some embodiments of the present disclosure. The memory array 1000 is an array of memory cells 1005-11, 1005-12, 1005-21, and 1005-22 (collectively referred to as “memory cells 1005” or “memory cell 1005”), which are arranged in rows 1010-1 and 1010-2 (collectively referred to as “rows 1010” or “row 1010”) and columns 1012-1 and 1012-2 (collectively referred to as “columns 1012” or “column 1012”). Each memory cell 1005 is illustrated within one of the dashed boxes in FIG. 10.

The memory array 1000 also includes three types of control lines: BLs 1040-1 and 1040-2 (collectively referred to as “BLs 1040” or “BL 1040”), WLs 1050-1 and 1050-2 (collectively referred to as “WLs 1050” or “WL 1050”), and platelines (PLs) 1060-1 and 1060-2 (collectively referred to as “PLs 1060” or “PL 1060”), which control the memory cells 1005. The memory cells 1005 in the row 1010-1 are coupled to the same BL 1040-1. The memory cells in the row 1010-1 are coupled to the same BL 1040-2. The memory cells in the column 1012-1 are coupled to the same WL 1050-2 and the same PL 1060-2. The memory cells in the column 1012-2 are coupled to the same WL 1050-1 and the same PL 1060-1. As is conventionally used in context of memory, the terms “row” and “column” do not reflect the, respectively, horizontal and vertical orientation on a page of a drawing illustrating a memory array but, instead, reflect how individual memory cells are addressed. Namely, memory cells 1005 sharing a single BL 1040 are said to be in the same row, while memory cells sharing a single WL 1050 and a single PL 1060 are said to be on the same column. In other embodiments, the memory array 1000 may include a different number of memory cells, BLs, WLs, or PLs. Furthermore, in other embodiments, the memory cells 1005 may be arranged in arrays in a manner other than what is shown in FIG. 10, e.g., in any suitable manner of arranging memory cells into arrays as known in the art, all of which being within the scope of the present disclosure.

A memory cell 1005 may store one bit of binary information. Each memory cell 1005 is a 1T-1X memory cell. The memory cell 1005 includes a memory element 1020 and an access transistor 1030. The memory element 1020 is configured to store signals. The memory element 1020 may have more than one states. The memory element 1020 having two states may be referred to as a binary memory element. In other embodiments, the memory element 1020 may have more than two states. In some embodiments, the memory element 1020 is a capacitor that can store electrical voltage signals, and the memory cell 1005 is a one-transistor one-capacitor (1T-1C) memory cell. In other embodiments, the memory element 1020 may be, for example, a ferroelectric memory element, a magnetic storage element, a resistor, or another transistor, coupled to the access transistor 1030. Also, the memory element 1020 may store signals other than electrical voltage signals.

The access transistor 1030 controls access to the memory cell 1005. For instance, the access transistor 1030 controls access to write information to the memory cell 1005, access to read information from the memory cell 1005, or both. The access transistor 1030 has a gate terminal, a source terminal, and a drain terminal, indicated in the example of FIG. 10 as terminals G, S, and D, respectively. Examples of the access transistor 1030 may include the transistors described above in conjunction with FIGS. 1, 7A, 7B, and 8.

As shown in FIG. 10, the gate terminal of the access transistor 1030 is coupled to a WL 1050, one of the S/D terminals of the access transistor 1030 is coupled to a BL 1040, and the other one of the S/D terminals of the access transistor 1030 is coupled to a first terminal of the memory element 1020, e.g., a first electrode of a capacitor. As also shown in FIG. 10, the other terminal of the memory element 1020 may be coupled to a capacitor PL 1060. As is known in the art, WL, BL, and PL may be used together to read and program the memory element 1020. In some embodiments (e.g., embodiments where the access transistor 1030 is the vertical transistor 105), a portion of the BL 1040 may be a S/D region of the access transistor 1030. Another S/D region of the access transistor 1030 is coupled to the memory element 1020. Also, a portion of the WL 1050 may be a gate electrode of the access transistor 1030. Such vertical transistors can improve the memory cell density of the memory array 1000 so that more memory cells can be arranged in the available space of the memory array 1000.

Each of the BL 1040, the WL 1050, and the PL 1060, as well as intermediate elements coupling these lines to various terminals described herein, may be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

In the embodiment of FIG. 10, a single PL 1060 is shared among multiple memory cells 1005 of a given row. The PLs 1060 are shared among the same memory cells 1005 among which the WL 1050 are shared. Such an arrangement where the PLs 1060 are shared among the same memory cells among which the WLs 1050 are shared may be described as an arrangement where the PLs 1060 are “parallel” to the WLs 1050. Each memory cell 1005 of the memory array 1000 where the PLs 1060 are parallel to the WLs 1050, e.g., as shown in FIG. 10, may then be addressed (e.g., to perform READ and WRITE operations) by using the WL 1050 and the PL 1060 corresponding to the column 1012 to which the memory cell 1005 belongs and by using the BL 1040 corresponding to the row 1010 to which the memory cell 1005 belongs.

It should be noted that, just as the horizontal and vertical orientations on a page of an electrical circuit diagram illustrating a memory array does imply functional division of memory cells into rows and columns as used in common language, the orientation of various elements on a page of an electrical circuit diagram illustrating a memory array does not imply that the same orientation is used for the actual physical layout of a memory array. For example, in an IC device implementing the memory array 1000, corresponding BLs 1040 and PLs 1060 (i.e., a pair of a BL 1040 and a PL 1060 coupled to a given column 1012) do not have to physically extend in a direction parallel to one another (although they may), or the WLs 1050 do not have to physically extend in a direction perpendicular to the BLs 1040 (although they may). In another example, in an IC device implementing the memory array 1000 as shown in FIG. 10, corresponding WLs 1050 and PLs 1060 (i.e., a pair of a WL 1050 and a PL 1060 coupled to a given column 1012) do not have to physically extend in a direction parallel to one another (although they may), or the WLs 1050 do not have to physically extend in a direction perpendicular to the BLs 1040 (although they may).

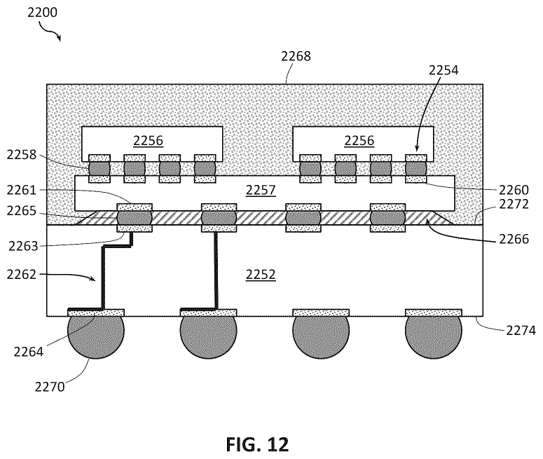

FIGS. 11A-11B are top views of a wafer 2000 and dies 2002 that may include one or more CMOS circuits with heterogeneous semiconductor orientations, according to some embodiments of the disclosure. In some embodiments, the dies 2002 may be included in an IC package, according to some embodiments of the disclosure. For example, any of the dies 2002 may serve as any of the dies 2256 in an IC package 2200 shown in FIG. 12. The wafer 2000 may be composed of semiconductor material and may include one or more dies 2002 having IC devices formed on a surface of the wafer 2000. Each of the dies 2002 may be a repeating unit of a semiconductor product that includes any suitable IC (e.g., ICs with heterogenous semiconductor orientation as described herein, including the IC devices 100, 700, 705, and 800). After the fabrication of the semiconductor product is complete (e.g., after manufacture of one or more CMOS circuits with heterogeneous semiconductor orientations as described herein), the wafer 2000 may undergo a singulation process in which each of the dies 2002 is separated from one another to provide discrete “chips” of the semiconductor product. In particular, devices that include one or more CMOS circuits with heterogeneous semiconductor orientations as disclosed herein may take the form of the wafer 2000 (e.g., not singulated) or the form of the die 2002 (e.g., singulated). The die 2002 may include one or more diodes, one or more transistors (e.g., one or more Ill-N transistors as described herein) as well as, optionally, supporting circuitry to route electrical signals to the Ill-N diodes with n-doped wells and capping layers and Ill-N transistors, as well as any other IC components. In some embodiments, the wafer 2000 or the die 2002 may implement an electrostatic discharge (ESD) protection device, an radio frequency front-end device, a memory device (e.g., a SRAM device), a logic device (e.g., an AND, OR, NAND, or NOR gate), or any other suitable circuit element. Multiple ones of these devices may be combined on a single die 2002.

FIG. 12 is a side, cross-sectional view of an example IC package 2200 that may include one or more IC devices having heterogeneous semiconductor orientations, according to some embodiments of the disclosure. In some embodiments, the IC package 2200 may be a system-in-package (SiP).

As shown in FIG. 12, the IC package 2200 may include a package substrate 2252. The package substrate 2252 may be formed of a dielectric material (e.g., a ceramic, a glass, a combination of organic and inorganic materials, a buildup film, an epoxy film having filler particles therein, etc., and may have embedded portions having different materials), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 12 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 12 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

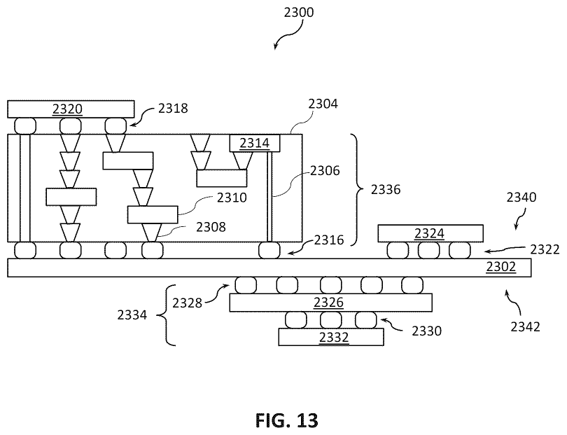

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 12 are solder balls (e.g., for a ball grid array arrangement), but any suitable second-level interconnects 2270 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 13.

The dies 2256 may take the form of any of the embodiments of the die 2002 discussed herein and may include any of the embodiments of an IC device having one or more CMOS circuits with heterogeneous semiconductor orientations. In embodiments in which the IC package 2200 includes multiple dies 2256, the IC package 2200 may be referred to as a multi-chip package. Importantly, even in such embodiments of an MCP implementation of the IC package 2200, one or more CMOS circuits with heterogeneous semiconductor orientations may be provided in a single chip, in accordance with any of the embodiments described herein. The dies 2256 may include circuitry to perform any desired functionality. For example, one or more of the dies 2256 may be ESD protection dies, including one or more CMOS circuits with heterogeneous semiconductor orientations as described herein, one or more of the dies 2256 may be logic dies (e.g., silicon-based dies), one or more of the dies 2256 may be memory dies (e.g., high bandwidth memory), etc. In some embodiments, any of the dies 2256 may include one or more CMOS circuits with heterogeneous semiconductor orientations, e.g., as discussed above; in some embodiments, at least some of the dies 2256 may not include any Ill-N diodes with n-doped wells and capping layers.

The IC package 2200 illustrated in FIG. 12 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 12, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 13 is a cross-sectional side view of an IC device assembly 2300 that may include components having one or more IC devices implementing heterogeneous semiconductor orientations, according to some embodiments of the disclosure. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of the IC devices implementing one or more CMOS circuits with heterogeneous semiconductor orientations in accordance with any of the embodiments disclosed herein; e.g., any of the IC packages discussed below with reference to the IC device assembly 2300 may take the form of any of the embodiments of the IC package 2200 discussed above with reference to FIG. 12 (e.g., may include one or more CMOS circuits with heterogeneous semiconductor orientations in/on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 13 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 13), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 11B), an IC device (e.g., the IC device of FIGS. 1-2), or any other suitable component. In particular, the IC package 2320 may include one or more CMOS circuits with heterogeneous semiconductor orientations as described herein. Although a single IC package 2320 is shown in FIG. 13, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 13, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as Si, Ge, and other Group Ill-V and Group IV materials. The interposer 2304 may include metal interconnects 2308 and vias 2310, including but not limited to TSVs 2306. The interposer 2304 may further include embedded devices 2314, including both passive and active devices. Such devices may include, but are not limited to, capacitors, decoupling capacitors, resistors, inductors, fuses, diodes, transformers, sensors, ESD protection devices, and memory devices. More complex devices such as further RF devices, power amplifiers, power management devices, antennas, arrays, sensors, and microelectromechanical systems (MEMS) devices may also be formed on the interposer 2304. In some embodiments, the IC devices implementing one or more CMOS circuits with heterogeneous semiconductor orientations as described herein may also be implemented in/on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 13 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

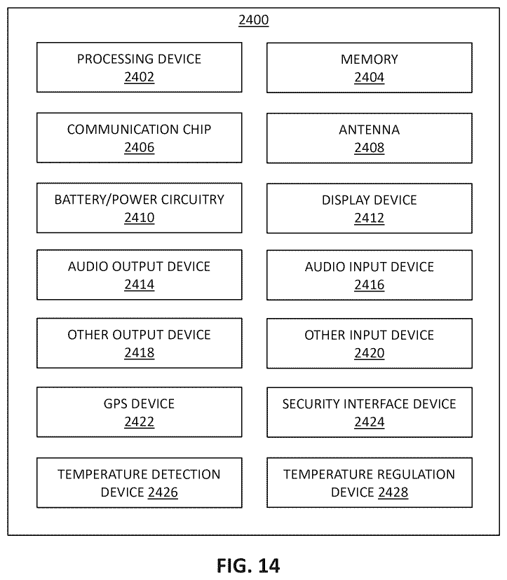

FIG. 14 is a block diagram of an example computing device 2400 that may include one or more components including one or more CMOS circuits with heterogeneous semiconductor orientations, according to some embodiments of the disclosure. For example, any suitable ones of the components of the computing device 2400 may include a die (e.g., the die 2002 (FIG. 11B)) having one or more CMOS circuits with heterogeneous semiconductor orientations. Any one or more of the components of the computing device 2400 may include, or be included in, an IC package 2200 (FIG. 12). Any one or more of the components of the computing device 2400 may include, or be included in, an IC device assembly 2300 (FIG. 13).

A number of components are illustrated in FIG. 14 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single system-on-a-chip (SoC) die.

Additionally, in various embodiments, the computing device 2400 may not include one or more of the components illustrated in FIG. 14, but the computing device 2400 may include interface circuitry for coupling to the one or more components. For example, the computing device 2400 may not include a display device 2412, but may include display device interface circuitry (e.g., a connector and driver circuitry) to which a display device 2412 may be coupled. In another set of examples, the computing device 2400 may not include an audio input device 2416 or an audio output device 2414, but may include audio input or output device interface circuitry (e.g., connectors and supporting circuitry) to which an audio input device 2416 or audio output device 2414 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid state memory, and/or a hard drive. In some embodiments, the memory 2404 may include memory that shares a die with the processing device 2402. This memory may be used as cache memory and may include embedded DRAM (eDRAM) or spin transfer torque magnetic random-access memory (STT-MRAM).

In some embodiments, the computing device 2400 may include a communication chip 2406 (e.g., one or more communication chips). For example, the communication chip 2406 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2406 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2406 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2406 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2406 may operate in accordance with other wireless protocols in other embodiments. The computing device 2400 may include an antenna 2408 to facilitate wireless communications and/or to receive other wireless communications (such as AM or FM radio transmissions).

In some embodiments, the communication chip 2406 may manage wired communications, such as electrical, optical, or any other suitable communication protocols (e.g., the Ethernet). As noted above, the communication chip 2406 may include multiple communication chips. For instance, a first communication chip 2406 may be dedicated to shorter-range wireless communications such as Wi-Fi or Bluetooth, and a second communication chip 2406 may be dedicated to longer-range wireless communications such as global positioning system (GPS), EDGE, GPRS, CDMA, WiMAX, LTE, EV-DO, or others. In some embodiments, a first communication chip 2406 may be dedicated to wireless communications, and a second communication chip 2406 may be dedicated to wired communications.

The computing device 2400 may include a battery/power circuitry 2410. The battery/power circuitry 2410 may include one or more energy storage devices (e.g., batteries or capacitors) and/or circuitry for coupling components of the computing device 2400 to an energy source separate from the computing device 2400 (e.g., AC line power).

The computing device 2400 may include a display device 2412 (or corresponding interface circuitry, as discussed above). The display device 2412 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2414 (or corresponding interface circuitry, as discussed above). The audio output device 2414 may include any device that generates an audible indicator, such as speakers, headsets, or earbuds, for example.

The computing device 2400 may include an audio input device 2416 (or corresponding interface circuitry, as discussed above). The audio input device 2416 may include any device that generates a signal representative of a sound, such as microphones, microphone arrays, or digital instruments (e.g., instruments having a musical instrument digital interface (MIDI) output).

The computing device 2400 may include an other output device 2418 (or corresponding interface circuitry, as discussed above). Examples of the other output device 2418 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may include a GPS device 2422 (or corresponding interface circuitry, as discussed above). The GPS device 2422 may be in communication with a satellite-based system and may receive a location of the computing device 2400, as known in the art.

The computing device 2400 may include a security interface device 2424. The security interface device 2424 may include any device that provides security features for the computing device 2400 or for any individual components therein (e.g., for the processing device 2402 or for the memory 2404). Examples of security features may include authorization, access to digital certificates, access to items in keychains, etc. Examples of the security interface device 2424 may include a software firewall, a hardware firewall, an antivirus, a content filtering device, or an intrusion detection device.

In some embodiments, the computing device 2400 may include a temperature detection device 2426 and a temperature regulation device 2428.

The temperature detection device 2426 may include any device capable of determining temperatures of the computing device 2400 or of any individual components therein (e.g., temperatures of the processing device 2402 or of the memory 2404). In various embodiments, the temperature detection device 2426 may be configured to determine temperatures of an object (e.g., the computing device 2400, components of the computing device 2400, devices coupled to the computing device, etc.), temperatures of an environment (e.g., a data center that includes, is controlled by, or otherwise associated with the computing device 2400), and so on. The temperature detection device 2426 may include one or more temperature sensors. Different temperature sensors of the temperature detection device 2426 may have different locations within and around the computing device 2400. A temperature sensor may generate data (e.g., digital data) representing detected temperatures and provide the data to another device, e.g., to the temperature regulation device 2428, the processing device 2402, the memory 2404, etc. In some embodiments, a temperature sensor of the temperature detection device 2426 may be turned on or off, e.g., by the processing device 2402 or an external system. The temperature sensor detects temperatures when it is on and does not detect temperatures when it is off. In other embodiments, a temperature sensor of the temperature detection device 2426 may detect temperatures continuously and automatically or detect temperatures at predefined times or at times triggered by an event associated with the computing device 2400 or any components therein.

The temperature regulation device 2428 may include any device configured to change (e.g., decrease) temperatures, e.g., based on one or more target temperatures and/or based on temperature measurements performed by the temperature detection device 2426. A target temperature may be a preferred temperature. A target temperature may depend on a setting in which the computing device 2400 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 2400 can be different. In some embodiments, cooling provided by the temperature regulation device 2428 may be a multi-stage process with temperatures ranging from room temperature to 4K or lower.

In some embodiments, the temperature regulation device 2428 may include one or more cooling devices. Different cooling device may have different locations within and around the computing device 2400. A cooling device of the temperature regulation device 2428 may be associated with one or more temperature sensors of the temperature detection device 2426 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 2400 is satisfied. In response to determining that one or more temperature-related condition associated with the temperature of the computing device 2400 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 2428 may operate with various cooling mechanisms, such as evaporation cooling, radiation cooling, conduction cooling, convection cooling, other cooling mechanisms, or any combination thereof. A cooling device of the temperature regulation device 2428 may include a cooling agent, such as a water, oil, liquid nitrogen, liquid helium, etc. In some embodiments, the temperature regulation device 2428 may be, for example, a dilution refrigerator, a helium-3 refrigerator, or a liquid helium refrigerator. In some embodiments, the temperature regulation device 2428 or any portions thereof (e.g., one or more of the individual cooling devices) may be connected to the computing device 2400 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 2400 (or components thereof) can be reduced, while the computing efficiency may be improved. For example, when the computing device 2400 (or components thereof) operates at lower temperatures, energy dissipation (e.g., heat dissipation) may be reduced. Further, energy consumed by semiconductor components (e.g., energy needed for switching transistors of any of the components of the computing device 2400) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy correlates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

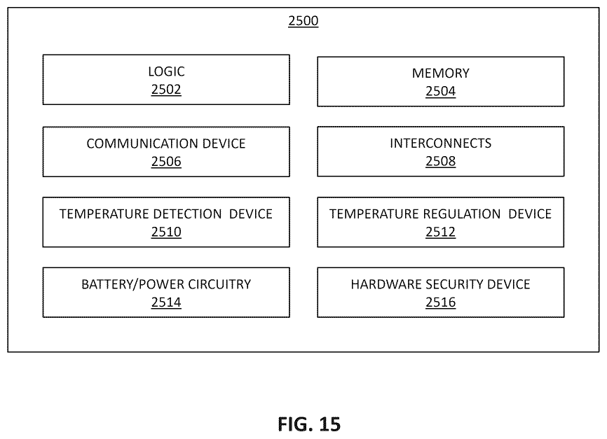

FIG. 15 is a block diagram of an example processing device 2500 that may include one or more CMOS circuits with heterogeneous semiconductor orientations, according to some embodiments of the disclosure. For example, any suitable ones of the components of the processing device 2500 may include a die (e.g., the die 2002 (FIG. 11B)) having one or more CMOS circuits with heterogeneous semiconductor orientations. Any one or more of the components of the processing device 2500 may include, or be included in, an IC package 2200 (FIG. 12). Any one or more of the components of the processing device 2500 may include, or be included in, an IC device assembly 2300 (FIG. 13). Any one or more of the components of the processing device 2500 may include, or be included in, a computing device 2400 (FIG. 14); for example, the processing device 2500 may be the processing device 2402 of the computing device 2400.

A number of components are illustrated in FIG. 15 as included in the processing device 2500, but any one or more of these components may be omitted or duplicated, as suitable for the application. In some embodiments, some or all of the components included in the processing device 2500 may be attached to one or more motherboards. In some embodiments, some or all of these components are fabricated on a single SoC die or coupled to a single support structure, e.g., to a single carrier substrate.

Additionally, in various embodiments, the processing device 2500 may not include one or more of the components illustrated in FIG. 15, but the processing device 2500 may include interface circuitry for coupling to the one or more components. For example, the processing device 2500 may not include a memory 2504, but may include display device interface circuitry (e.g., a connector and driver circuitry) to which a memory 2504 may be coupled.

The processing device 2500 may include logic circuitry 2502 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 2502 may include one or more circuits responsible for read/write operations with respect to the data stored in the memory 2504. To that end, the logic circuitry 2502 may include one or more I/O ICs configured to control access to data stored in the memory 2504.

In some embodiments, the logic circuitry 2502 may include one or more high-performance compute dies, configured to perform various operations with respect to data stored in the memory 2504 (e.g., arithmetic and logic operations, pipelining of data from one or more memory dies of the memory 2504, and possibly also data from external devices/chips). In some embodiments, the logic circuitry 2502 may be configured to only control I/O access to data but not perform any operations on the data. In some embodiments, the logic circuitry 2502 may implement ICs configured to implement I/O control of data stored in the memory 2504, assemble data from the memory 2504 for transport (e.g., transport over a central bus) to devices/chips that are either internal or external to the processing device 2500, etc. In some embodiments, the logic circuitry 2502 may not be configured to perform any operations on the data besides I/O and assembling for transport to the memory 2504.

The processing device 2500 may include a memory 2504, which may include one or more ICs configure to implement memory circuitry (e.g., ICs implementing one or more of memory devices, memory arrays, control logic configured to control the memory devices and arrays, etc.). In some embodiments, the memory 2504 may be implemented substantially as described above with reference to the memory 2404 (FIG. 14). In some embodiments, the memory 2504 may be a designated device configured to provide storage functionality for the components of the processing device 2500 (i.e., local), while the memory 2404 may be configured to provide system-level storage functionality for the entire computing device 2400 (i.e., global). In some embodiments, the memory 2504 may include memory that shares a die with the logic circuitry 2502.

In some embodiments, the memory 2504 may include a flat memory (also sometimes referred to as a “flat hierarchy memory” or a “linear memory”) and, therefore, may also be referred to as a “basin memory.” As known in the art, a flat memory or a linear memory refers to a memory addressing paradigm in which memory may appear to the program as a single contiguous address space, where a processor can directly and linearly address all of the available memory locations without having to resort to memory segmentation or paging schemes. Thus, the memory implemented in the memory 2504 may be a memory that is not divided into hierarchical layer or levels in terms of access to its data.

In some embodiments, the memory 2504 may include a hierarchical memory. In this context, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, i.e., the size and capabilities of each component. With hierarchical memory, each of the various memory components can be viewed as part of a hierarchy of memories (m1, m2, . . . , mn) in which each member mi is typically smaller and faster than the next highest member mi+1 of the hierarchy. To limit waiting by higher levels, a lower level of a hierarchical memory structure may respond by filling a buffer and then signaling for activating the transfer. For example, in some embodiments, the hierarchical memory implemented in the memory 2504 may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how the memory 2504 may be arranged.

The processing device 2500 may include a communication device 2506, which may be implemented substantially as described above with reference to the communication chip 2406 (FIG. 14). In some embodiments, the communication device 2506 may be a designated device configured to provide communication functionality for the components of the processing device 2500 (i.e., local), while the communication chip 2406 may be configured to provide system-level communication functionality for the entire computing device 2400 (i.e., global).

The processing device 2500 may include interconnects 2508, which may include any element or device that includes an electrically conductive material for providing electrical connectivity to one or more components of, or associated with, a processing device 2500 or/and between various such components. Examples of the interconnects 2508 include conductive lines/wires (also sometimes referred to as “lines” or “metal lines” or “trenches”) and conductive vias (also sometimes referred to as “vias” or “metal vias”), metallization stacks, redistribution layers, metal-insulator-metal (MIM) structures, etc.

The processing device 2500 may include a temperature detection device 2510 which may be implemented substantially as described above with reference to the temperature detection device 2426 (FIG. 14) but configured to determine temperatures on a more local scale, i.e., of the processing device 2500 of components thereof. In some embodiments, the temperature detection device 2510 may be a designated device configured to provide temperature detection functionality for the components of the processing device 2500 (i.e., local), while the temperature detection device 2426 may be configured to provide system-level temperature detection functionality for the entire computing device 2400 (i.e., global).

The processing device 2500 may include a temperature regulation device 2512 which may be implemented substantially as described above with reference to the temperature regulation device 2428 (FIG. 14) but configured to regulate temperatures on a more local scale, i.e., of the processing device 2500 of components thereof. In some embodiments, the temperature regulation device 2512 may be a designated device configured to provide temperature regulation functionality for the components of the processing device 2500 (i.e., local), while the temperature regulation device 2428 may be configured to provide system-level temperature regulation functionality for the entire computing device 2400 (i.e., global).

The processing device 2500 may include a battery/power circuitry 2514 which may be implemented substantially as described above with reference to the battery/power circuitry 2410 (FIG. 14). In some embodiments, the battery/power circuitry 2514 may be a designated device configured to provide battery/power functionality for the components of the processing device 2500 (i.e., local), while the battery/power circuitry 2410 may be configured to provide system-level battery/power functionality for the entire computing device 2400 (i.e., global).

The processing device 2500 may include a hardware security device 2516 which may be implemented substantially as described above with reference to the security interface device 2424 (FIG. 14). In some embodiments, the hardware security device 2516 may be a physical computing device configured to safeguard and manage digital keys, perform encryption and decryption functions for digital signatures, authentication, and other cryptographic functions. In some embodiments, the hardware security device 2516 may include one or more secure cryptoprocessors chips.

The following paragraphs provide various examples of the embodiments disclosed herein.

Example 1 provides an IC device, including a P-type transistor including a first semiconductor structure, the first semiconductor structure having a first crystal direction; and a N-type transistor including a second semiconductor structure, the second semiconductor structure having a second crystal direction, in which an angle between the first crystal direction and the second crystal direction is greater than 50 degrees.

Example 2 provides the IC device according to example 1, in which the first crystal direction is a [100] direction, and the second crystal direction is a [111] direction.

Example 3 provides the IC device according to example 1 or 2, in which the first semiconductor structure or the second semiconductor structure includes Ge, InGaAs, GaAs, InAs, SiGe, or GaN.

Example 4 provides the IC device according to any one of examples 1-3, further including a third semiconductor structure that includes a different semiconductor material from the first semiconductor structure or the second semiconductor structure.

Example 5 provides the IC device according to example 4, in which the third semiconductor structure has a third crystal direction that is aligned with the second crystal direction.

Example 6 provides the IC device according to any one of examples 1-5, in which the first semiconductor structure or the second semiconductor structure has a three-dimensional shape, and the three-dimensional shape is a fin, nanowire, or nanoribbon.

Example 7 provides the IC device according to any one of examples 1-6, further including a conductive structure wrapping around a portion of the first semiconductor structure and a portion of the second semiconductor structure.

Example 8 provides an IC device, including a first semiconductor structure, in which Miller indices of a surface of the first semiconductor structure are (111); a second semiconductor structure, in which Miller indices of a surface of the second semiconductor structure are (100); and a third semiconductor structure, in which Miller indices of a surface of the third semiconductor structure are (100), in which the first semiconductor structure and the second semiconductor structure comprise different types of dopants.

Example 9 provides the IC device according to example 8, in which the first semiconductor structure includes a channel of an N-type transistor, and the second semiconductor structure includes a channel of a P-type transistor.

Example 10 provides the IC device according to example 8 or 9, further including an electrical insulator between the first semiconductor structure and the second semiconductor structure.

Example 11 provides the IC device according to any one of examples 8-10, in which the first semiconductor structure or the second semiconductor structure includes a different semiconductor material from the third semiconductor structure.

Example 12 provides the IC device according to example 11, in which the first semiconductor structure or the second semiconductor structure includes Ge, InGaAs, GaAs, InAs, SiGe, or GaN, and the third semiconductor structure includes silicon.

Example 13 provides the IC device according to any one of examples 8-12, in which the surface of the first semiconductor structure and the surface of the second semiconductor structure are in parallel.

Example 14 provides the IC device according to any one of examples 8-13, in which the second semiconductor structure is between the first semiconductor structure and the third semiconductor structure.

Example 15 provides a method for forming an IC structure, including forming a first semiconductor structure with a first crystal direction over a first device region; forming an insulator layer over the first semiconductor structure; forming a second semiconductor structure with a second crystal direction over a second device region, the second crystal direction different from the first crystal direction; and coupling the insulator layer and the second semiconductor structure so that the insulator layer is between the first semiconductor structure and the second semiconductor structure.

Example 16 provides the method according to example 15, further including removing the first device region after the insulator layer and the second semiconductor structure are bonded.

Example 17 provides the method according to example 16, in which forming the first semiconductor structure includes forming a semiconductor layer and a dielectric layer between the first semiconductor structure and the first device region.

Example 18 provides the method according to example 17, further including removing the semiconductor layer and the dielectric layer after the insulator layer and the second semiconductor structure are bonded.

Example 19 provides the method according to any one of examples 15-18, in which the first crystal direction is [111], and the second crystal direction is [100].

Example 20 provides the method according to any one of examples 15-19, in which the first semiconductor structure includes a channel of an N-type transistor, and the second semiconductor structure includes a channel of a P-type transistor.

Example 21 provides an IC package, including the IC device any one of examples 1-20; and a further IC component, coupled to the IC device.

Example 22 provides the IC package according to example 21, where the further IC component includes one of a package substrate, an interposer, or a further IC die.

Example 23 provides the IC package according to example 21 or 22, where the IC device may include, or be a part of, at least one of a memory device, a computing device, a wearable device, a handheld electronic device, and a wireless communications device.

Example 24 provides an electronic device, including a carrier substrate; and the IC package according to any one of examples 21-23, coupled to the carrier substrate.

Example 25 provides the electronic device according to example 24, where the carrier substrate is a motherboard.

Example 26 provides the electronic device according to example 24, where the carrier substrate is a PCB.

Example 27 provides the electronic device according to any one of examples 24-26, where the electronic device is a wearable electronic device or handheld electronic device.

Example 28 provides the electronic device according to any one of examples 24-27, where the electronic device further includes one or more communication chips and an antenna.

Example 29 provides the electronic device according to any one of examples 24-28, where the electronic device is an RF transceiver.

Example 30 provides the electronic device according to any one of examples 24-28, where the electronic device is one of a switch, a power amplifier, a low-noise amplifier, a filter, a filter bank, a duplexer, an upconverter, or a downconverter of an RF communications device, e.g., of an RF transceiver.

Example 31 provides the electronic device according to any one of examples 24-30, where the electronic device is a computing device.

Example 32 provides the electronic device according to any one of examples 24-31, where the electronic device is included in a base station of a wireless communication system.

Example 33 provides the electronic device according to any one of examples 24-31, where the electronic device is included in a user equipment device of a wireless communication system.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a P-type transistor comprising a first semiconductor structure, the first semiconductor structure having a first crystal direction; and
a N-type transistor comprising a second semiconductor structure, the second semiconductor structure having a second crystal direction,
wherein an angle between the first crystal direction and the second crystal direction is greater than 50 degrees.

2. The IC device according to claim 1, wherein the first crystal direction is a [100] direction, and the second crystal direction is a [111] direction.

3. The IC device according to claim 1, wherein the first semiconductor structure or the second semiconductor structure comprises germanium, indium gallium arsenide, gallium arsenide, indium arsenide, silicon germanium, or gallium nitride.

4. The IC device according to claim 1, further comprising:
a third semiconductor structure that comprises a different semiconductor material from the first semiconductor structure or the second semiconductor structure.

5. The IC device according to claim 4, wherein the third semiconductor structure has a third crystal direction that is aligned with the second crystal direction.

6. The IC device according to claim 1, wherein the first semiconductor structure or the second semiconductor structure has a three-dimensional shape, and the three-dimensional shape is a fin, nanowire, or nanoribbon.

7. The IC device according to claim 1, further comprising:
a conductive structure wrapping around a portion of the first semiconductor structure and a portion of the second semiconductor structure.

8. An integrated circuit (IC) device, comprising:
a first semiconductor structure, wherein Miller indices of a surface of the first semiconductor structure are (111);
a second semiconductor structure, wherein Miller indices of a surface of the second semiconductor structure are (100); and
a third semiconductor structure, wherein Miller indices of a surface of the third semiconductor structure are (100),
wherein the first semiconductor structure and the second semiconductor structure comprise different types of dopants.

9. The IC device according to claim 8, wherein the first semiconductor structure comprises a channel of an N-type transistor, and the second semiconductor structure comprises a channel of a P-type transistor.

10. The IC device according to claim 8, further comprising:
an electrical insulator between the first semiconductor structure and the second semiconductor structure.

11. The IC device according to claim 8, wherein the first semiconductor structure or the second semiconductor structure comprises a different semiconductor material from the third semiconductor structure.

12. The IC device according to claim 11, wherein the first semiconductor structure or the second semiconductor structure comprises germanium, indium gallium arsenide, gallium arsenide, indium arsenide, silicon germanium, or gallium nitride, and the third semiconductor structure comprises silicon.

13. The IC device according to claim 8, wherein the surface of the first semiconductor structure and the surface of the second semiconductor structure are in parallel.

14. The IC device according to claim 8, wherein the second semiconductor structure is between the first semiconductor structure and the third semiconductor structure.

15. A method for forming an integrated circuit (IC) structure, comprising:
forming a first semiconductor structure with a first crystal direction over a first device region;
forming an insulator layer over the first semiconductor structure;
forming a second semiconductor structure with a second crystal direction over a second device region, the second crystal direction different from the first crystal direction; and
coupling the insulator layer and the second semiconductor structure so that the insulator layer is between the first semiconductor structure and the second semiconductor structure.

16. The method according to claim 15, further comprising:
removing the first device region after the insulator layer and the second semiconductor structure are bonded.

17. The method according to claim 16, wherein forming the first semiconductor structure comprises:
forming a semiconductor layer and a dielectric layer between the first semiconductor structure and the first device region.

18. The method according to claim 17, further comprising:
removing the semiconductor layer and the dielectric layer after the insulator layer and the second semiconductor structure are bonded.

19. The method according to claim 15, wherein the first crystal direction is [111], and the second crystal direction is [100].

20. The method according to claim 15, wherein the first semiconductor structure comprises a channel of an N-type transistor, and the second semiconductor structure comprises a channel of a P-type transistor.
